(19) United States
(12) Patent Application Publication
(10) Pub. No.: US 2026/0100226 A1
(43) Pub. Date: Apr. 9, 2026

(54) NONVOLATILE MEMORY DEVICE INCLUDING PLURALITY OF STRING SELECTION TRANSISTORS

(71) Applicant: SAMSUNG ELECTRONICS CO., LTD., Suwon-si (KR)

(72) Inventors: Kibong Moon, Suwon-si (KR); Dajin Kim, Suwon-si (KR); Seungsob Kim, Suwon-si (KR); Sang-Yong Park, Suwon-si (KR); Seung Jae Baik, Suwon-si (KR); Gun-Wook Yoon, Suwon-si (KR); Nayeong Yun, Suwon-si (KR); Sung-Bok Lee, Suwon-si (KR); Jaeduk Lee, Suwon-si (KR)

(73) Assignee: SAMSUNG ELECTRONICS CO., LTD., Suwon-si (KR)

(21) Appl. No.: 19/313,150

(22) Filed: Aug. 28, 2025

(30) Foreign Application Priority Data
Oct. 7, 2024 (KR) 10-2024-0136071

(51) Int. Cl. G11C 16/04; G11C 16/08

(52) U.S. Cl. CPC G11C 16/0483; G11C 16/08

(57) ABSTRACT

A nonvolatile memory device includes a first cell string to an n-th cell string connected in parallel between a bit line and a common source line. Each of the first to n-th cell strings includes: a corresponding one of a first ground selection transistor to an n-th ground selection transistor respectively connected to a first ground selection line to an n-th ground selection line; and a first string selection transistor to an m-th string selection transistor respectively connected to a first string selection line to an m-th string selection line. Based on the first cell string being a selected cell string: the first to m-th string selection transistors of the first cell string are turned on, and at least one of the first to m-th string selection transistors of each of the second to n-th cell strings is turned off, where m and n are natural numbers, and m is less than or equal to n.

### CROSS-REFERENCE TO RELATED APPLICATIONS

This application claims priority under 35 U.S.C. § 119 to Korean Patent Application No. 10-2024-0136071 filed on Oct. 7, 2024, in the Korean Intellectual Property Office, the disclosure of which is incorporated by reference herein in its entirety.

### BACKGROUND

The present disclosure relates to a nonvolatile memory device, and more particularly, to a nonvolatile memory device including a plurality of string selection transistors.

A semiconductor memory is classified as a volatile memory device, which loses data stored therein when a power is turned off, such as a static random access memory (SRAM) or a dynamic random access memory (DRAM) or a nonvolatile memory device, which retains data stored therein even when a power is turned off, such as a flash memory, a phase-change RAM (PRAM), a magnetic RAM (MRAM), a resistive RAM (RRAM), or a ferroelectric RAM (FRAM).

The flash memory device is being widely used as a high-capacity storage medium. In general, the flash memory device stores data or read the stored data by controlling levels of various lines (e.g., a string selection line, a word line, a ground selection line, and a common source line) connected to a plurality of memory cells. When various lines are controlled individually in units of cell string, the reliability and performance of the flash memory device may be improved, but it is difficult to form lines individually due to the increase in complexity of the process of manufacturing the flash memory device.

### SUMMARY

Embodiments of the present disclosure provide a nonvolatile memory device including a plurality of string selection transistors which may provide improved performance and manufacturing cost efficiency.

According to an aspect of an embodiment, a nonvolatile memory device includes: a first cell string to an n-th cell string connected in parallel between a bit line and a common source line, wherein each of the first to n-th cell strings includes: a corresponding one of a first ground selection transistor to an n-th ground selection transistor respectively connected to a first ground selection line to an n-th ground selection line; and a first string selection transistor to an m-th string selection transistor respectively connected to a first string selection line to an m-th string selection line, wherein, based on the first cell string being a selected cell string: the first to m-th string selection transistors of the first cell string are turned on, and at least one of the first to m-th string selection transistors of each of the second to n-th cell strings is turned off, and wherein m and n are natural numbers, and m is less than or equal to n.

According to an aspect of an embodiment, a nonvolatile memory device includes: a first cell string to an n-th cell string connected between a bit line and each of a first common source line to an n-th common source line, wherein each of the first to n-th cell strings includes: a corresponding one a first ground selection transistor to an n-th ground selection transistor connected to a ground selection line; and a first string selection transistor to an m-th string selection transistor respectively connected to a first string selection line to an m-th string selection line, wherein, based on the first cell string being a selected cell string: the first to m-th string selection transistors of the first cell string are turned on, and at least one of the first to m-th string selection transistors of each of the second to n-th cell strings is turned off, and wherein the m and are natural numbers, and m is less than or equal to n.

According to an aspect of an embodiment, a nonvolatile memory device includes: a plurality of cell strings provided between a bit line and a common source line, each of the plurality of cell strings including a plurality of string selection transistors connected to a plurality of string selection lines, wherein, based on a first cell string among the plurality of cell strings being a selected cell string, in each of remaining unselected cell strings among the plurality of cell strings, at least one string selection transistor among the plurality of string selection transistors is turned off, and wherein a number of the plurality of cell strings is more than a number of the plurality of string selection lines.

### BRIEF DESCRIPTION OF THE DRAWINGS

The above and other aspects and features of the present disclosure will become apparent by describing in detail embodiments thereof with reference to the accompanying drawings, in which:

FIG. 1 is a block diagram illustrating a nonvolatile memory device according to an embodiment of the present disclosure;

FIGS. 2A and 2B are circuit diagrams illustrating examples of a first memory block according to an embodiment of the present disclosure;

FIG. 3 is a cross-sectional view illustrating a partial structure of a memory block according to an embodiment of the present disclosure;

FIG. 4 is a diagram for describing a BVNAND structure applicable to a nonvolatile memory device according to an embodiment of the present disclosure;

FIGS. 5A, 5B, and 5C are diagrams for describing a method of controlling a memory block, according to an embodiment of the present disclosure;

FIG. 6 is a diagram illustrating a string selection transistor coding pattern of string selection transistors of a memory block according to an embodiment of the present disclosure;

FIGS. 7A to 7F are diagrams for describing an operation of a memory block including string selection transistors programmed depending on the string selection transistor coding pattern of FIG. 6;

FIG. 8 is a diagram for describing a method of controlling a memory block, according to an embodiment of the present disclosure;

FIG. 9 is a diagram illustrating a string selection transistor coding pattern of string selection transistors of a memory block according to an embodiment of the present disclosure;

FIGS. 10A and 10B are diagrams for describing an operation of a memory block including string selection transistors programmed depending on the string selection transistor coding pattern of FIG. 9;

FIG. 11 is a diagram illustrating a string selection transistor coding pattern of string selection transistors of a memory block according to an embodiment of the present disclosure;

FIGS. 12A and 12B are diagrams for describing an operation of a memory block including string selection transistors programmed depending on the string selection transistor coding pattern of FIG. 11;

FIG. 13 is a diagram illustrating a string selection transistor coding pattern of string selection transistors of a memory block according to an embodiment of the present disclosure;

FIGS. 14A and 14B are diagrams for describing an operation of a memory block including string selection transistors programmed depending on the string selection transistor coding pattern of FIG. 13;

FIG. 15 is a block diagram illustrating a memory system according to an embodiment of the present disclosure; and

FIG. 16 is a diagram illustrating a system to which a storage device according to an embodiment of the present disclosure is applied.

### DETAILED DESCRIPTION

Below, example embodiments of the present disclosure will be described in detail and clearly to such an extent that an ordinary one in the art can carry out the present disclosure.

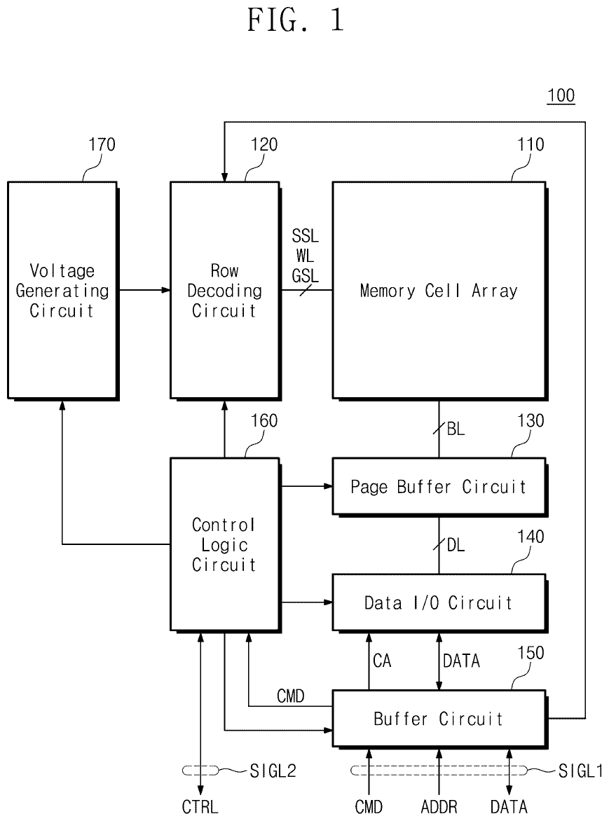

FIG. 1 is a block diagram illustrating a nonvolatile memory device according to an embodiment of the present disclosure. Referring to FIG. 1, a nonvolatile memory device 100 may include a memory cell array 110, a row decoding circuit 120, a page buffer circuit 130, a data input/output circuit 140, a buffer circuit 150, a control logic circuit 160, and a voltage generating circuit 170. In an embodiment, the nonvolatile memory device 100 may be a NAND flash memory. However, the present disclosure is not limited thereto, and the nonvolatile memory device 100 may be one of various different memory devices.

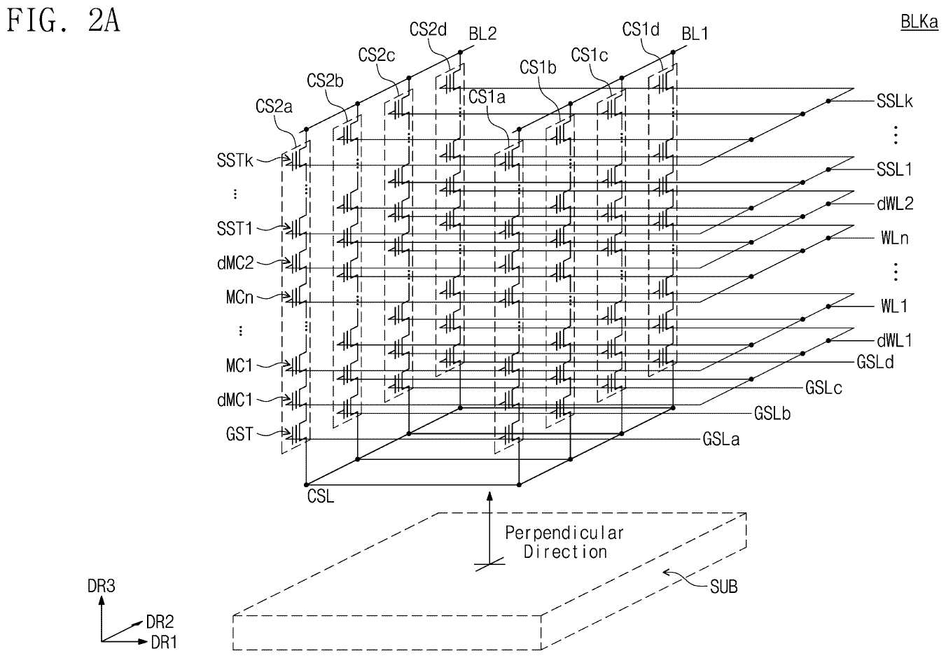

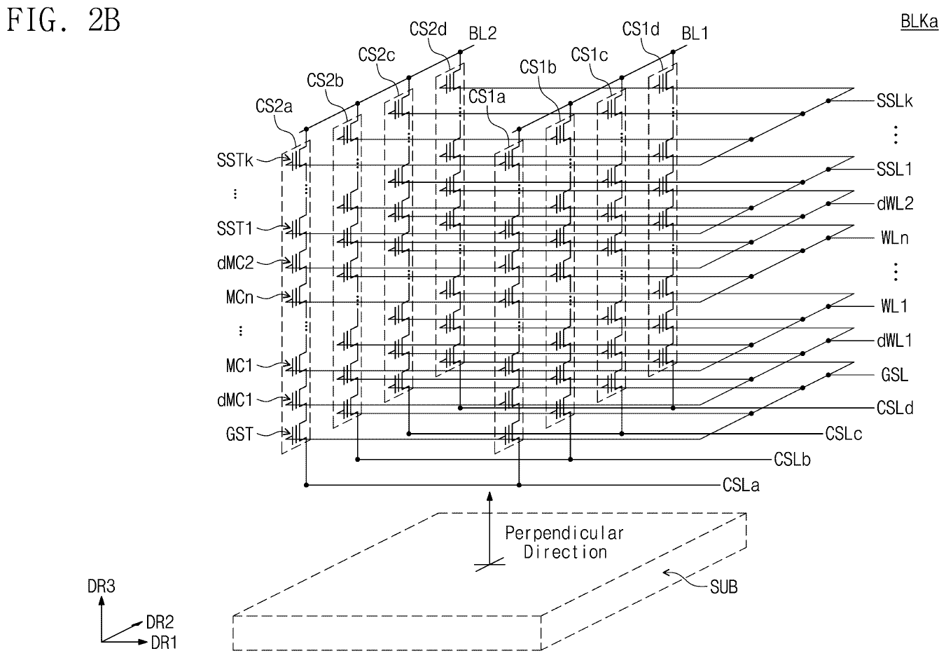

The memory cell array 110 may include a plurality of memory blocks. Each of the plurality of memory blocks may include a plurality of cell strings. Each of the plurality of cell strings may include a plurality of cell transistors stacked in a direction perpendicular to a substrate. The plurality of cell transistors may be connected in series between bit lines BL and a common source line. The plurality of cell transistors may be connected to string selection lines SSL, word lines WL, and ground selection lines GSL. The plurality of memory blocks will be described in detail with reference to FIGS. 2A and 2B.

The row decoding circuit 120 may be connected to the memory cell array 110 through the string selection lines SSL, the word lines WL, and the ground selection lines GSL. The row decoding circuit 120 may operate under control of the control logic circuit 160. For example, under control of the control logic circuit 160, the row decoding circuit 120 may decode a row address RA received from the buffer circuit 150; based on a decoding result, the row decoding circuit 120 may control or drive the string selection lines SSL, the word lines WL, and the ground selection lines GSL or may control voltages to be applied to the string selection lines SSL, the word lines WL, and the ground selection lines GSL.

The page buffer circuit 130 may be connected to the memory cell array 110 through the bit lines BL. The page buffer circuit 130 may be connected to the data input/output circuit 140 through a plurality of data lines DL. The page buffer circuit 130 may operate under control of the control logic circuit 160. For example, in the program operation of the nonvolatile memory device 100, the page buffer circuit 130 may store data to be programmed in the memory cell array 110 under control of the control logic circuit 160. In the read operation of the nonvolatile memory device 100, the page buffer circuit 130 may sense voltages of the plurality of bit lines BL and may store the sensed voltages as read data.

The data input/output circuit 140 may be connected to the page buffer circuit 130 through the plurality of data lines DL. The data input/output circuit 140 may receive a column address CA from the buffer circuit 150. The data input/output circuit 140 may transmit the data read by the page buffer circuit 130 to the buffer circuit 150 depending on the column Address CA. The data input/output circuit 140 may transmit the data received from the buffer circuit 150 to the page buffer circuit 130, based on the column address CA.

The buffer circuit 150 may receive a command CMD and an address ADDR from an external device (e.g., a controller) through first signal lines SIGL1 and may exchange data “DATA” with the external device (e.g., a controller) through the first signal lines SIGL1. In an embodiment, the first signal lines SIGL1 may include data signal lines (e.g., DQ lines) and a data strobe signal line (e.g., a DQS line).

The buffer circuit 150 may operate under control of the control logic circuit 160. For example, the control logic circuit 160 may exchange a control signal CTRL with the external device (e.g., a controller) through second signal lines SIGL2. The control logic circuit 160 may control the buffer circuit 150 based on the control signals CTRL such that the buffer circuit 150 routes the command CMD, the address ADDR, and the data “DATA”. Under control of the control logic circuit 160, the buffer circuit 150 may classify signals received through the first signal lines SIGL1 as the command CMD or the address ADDR. The buffer circuit 150 may transfer the command CMD to the control logic circuit 160. The buffer circuit 150 may transfer the row address RA of the address ADDR to the row decoding circuit 120 and may transfer the column address CA of the address ADDR to the data input/output circuit 140. The buffer circuit 150 may exchange the data “DATA” with the data input/output circuit 140.

The control logic circuit 160 may decode the command CMD received from the buffer circuit 150 and may control the nonvolatile memory device 100 or various components of the nonvolatile memory device 100 based on a decoding result.

Under control of the control logic circuit 160, the voltage generating circuit 170 may generate various operating voltages which are used in the nonvolatile memory device 100. In an embodiment, the operating voltages may include various voltages such as program voltages, pass voltages, selection read voltages, non-selection read voltages, erase voltages, and verify voltages. Below, various voltages which are used to describe embodiment of the present disclosure may be include in the operating voltages generated by the voltage generating circuit 170.

FIGS. 2A and 2B are circuit diagrams illustrating examples of a memory block according to an embodiment of the present disclosure. A structure of a memory block BLKa will be described with reference to FIGS. 2A and 2B, but the present disclosure is not limited thereto. For example, the memory cell array 110 may include a plurality of memory blocks, each of which is similar in structure to the memory block BLKa of FIGS. 2A and 2B.

In an embodiment, the memory block BLKa to be described with reference to FIGS. 2A and 2B may correspond to a physical erase unit of the nonvolatile memory device 100. However, the present disclosure is not limited thereto. For example, the nonvolatile memory device 100 may perform the erase operation in units of page, word line, sub-block, or plane.

In an embodiment, the memory block BLKa to be described with reference to FIGS. 2A and 2B is only an example. The number of cell strings may increase or decrease, and the number of rows of cell strings and the number of columns of cell strings may increase or decrease depending on the number of cell strings. Also, the numbers of cell transistors (e.g., GST, MC, dMC, and SST) of the memory block BLKa may increase or decrease, and the height of the memory block BLKa may increase or decrease depending of the numbers of cell transistors. In addition, the numbers of lines GSL, WL, dWL, and SSL connected to the cell transistors may increase or decrease depending on the number of cell transistors.

Referring to FIGS. 1 and 2A, a plurality of cell strings CS1a, CS1b, CS1c, CS1d, CS2a, CS2b, CS2c, and CS2d may be arranged on a substrate SUB in rows and columns. Each row may extend along a first direction DR1. Each column may extend along a second direction DR2. The plurality of cell strings CS1a to CS2d may be connected in common to a common source line CSL formed on (or in) the substrate SUB. In FIG. 2A, a location of the substrate SUB is depicted as an example for better understanding of the structure of the memory block BLKa.

The cell strings of each row may be connected in common to a plurality of string selection lines SSL1 to SSLk and may be connected to a corresponding ground selection line among ground selection lines GSLa, GSLb, GSLc, and GSLd. The cell strings of each column may be connected to a corresponding bit line among first and second bit lines BL1 and BL2. For example, the cell strings CS1a, CS1b, CS1c, and CS1d located at the same column, that is, at the first column may be connected to the first bit line BL1, and the cell strings CS2a, CS2b, CS2c, and CS2d located at the same column, that is, at the second column may be connected to the second bit line BL2. For example, the first and second bit lines BL1 and BL2 may be included in the bit lines BL.

Each cell string may include a plurality of memory cells MC1 to MCn respectively connected to a plurality of word lines WL1 to WLn, a plurality of dummy memory cells dMC1 and dMC2 respectively connected to a plurality of dummy word lines dWL1 and dWL2, and a plurality of string selection transistors SST1 to SSTk respectively connected to a plurality of string selection lines SSL1 to SSLk. The cell strings of the first row may further include a ground selection transistor GST connected to an a-th ground selection line GSLa. The cell strings of the second row may further include a ground selection transistor GST connected to a b-th ground selection line GSLb. The cell strings of the third row may further include a ground selection transistor GST connected to a c-th ground selection line GSLc. The cell strings of the fourth row may further include a ground selection transistor GST connected to a d-th ground selection line GSLd.

In each cell string, the ground selection transistor GST, the plurality of memory cells MC1 to MCn, the plurality of string selection transistors SST1 to SSTk may be connected in series in a direction perpendicular to the substrate SUB, for example, a third direction DR3 and may be sequentially stacked in the direction perpendicular to the substrate SUB.

In an embodiment, the first dummy memory cell dMC1 may be provided between the plurality of memory cells MC1 to MCn and the ground selection transistor GST. Also, in an embodiment, the second dummy memory cell dMC2 may be provided between the plurality of memory cells MC1 to MCn and the plurality of string selection transistors SST1 to SSTk. The dummy memory cell may not be programmed (e.g., may be program-inhibited) or may be programmed to be different from that of the plurality of memory cells MC1 to MCn.

In an embodiment, memory cells which are placed at the same height and are associated with one ground selection line GSLa, GSLb, GSLc, or GSLd may constitute one physical page. Memory cells of one physical page may be connected to one sub-word line. Sub-word lines of physical pages located at the same height may be connected in common to one word line. Below, the term “word line” may be used to indicate a word line or a sub-word line and may be interpreted based on the context.

As described above, the ground selection transistors GST of the plurality of cell strings CS1a to CS2d may be connected to the plurality of ground selection lines GSLa to GSLd. For example, ground selection transistors placed at the same row may be connected to the same ground selection line, and ground selection transistors placed at different rows may be connected to different ground selection lines. In detail, the ground selection transistors GST of the cell strings CS1a and CS2a placed at the first row may be connected to the a-th ground selection line GSLa; the ground selection transistors GST of the cell strings CS1b and CS2b placed at the second row may be connected to the b-th ground selection line GSLb; the ground selection transistors GST of the cell strings CS1c and CS2c placed at the third row may be connected to the c-th ground selection line GSLc; and, the ground selection transistors GST of the cell strings CS1d and CS2d placed at the fourth row may be connected to the d-th ground selection line GSLd.

For brevity of drawing and for convenience of description, the description will be given as each of the plurality of cell strings CS1a to CS2d includes one ground selection transistor GST, but the present disclosure is not limited thereto. Each of the plurality of cell strings CS1a to CS2d may include a plurality of ground selection transistors, and ground selection transistors placed at the same row from among ground selection transistors placed at the same height from the substrate may be connected to the same ground selection line; in this case, ground selection transistors placed at different rows may be connected to different ground selection lines.

Referring to FIGS. 1 and 2B, the plurality of cell strings CS1a, CS1b, CS1c, CS1d, CS2a, CS2b, CS2c, and CS2d may be arranged on the substrate SUB in rows and columns. Each row may extend along the first direction DR1. Each column may extend along the second direction DR2. The memory block BLKa of FIG. 2B may be implemented to be the same as the memory block BLKa of FIG. 2A except that cell strings of each row are connected in common to a ground selection line GSL and are connected to a corresponding common source line among a plurality of common source lines CSLa, CSLb, CSLc, and CSLd. Thus, additional description will be omitted to avoid redundancy.

As described above, string selection transistors placed at the same height from the substrate may be connected to the same string selection line. For example, the first string selection transistors SST1 of the plurality of cell strings CS1a to CS2d may be placed at the same height from the substrate and may be connected in common to the first string selection line SSL1. The k-th string selection transistors SSTk of the plurality of cell strings CS1a to CS2d may be placed at the same height from the substrate and may be connected in common to the k-th string selection line SSLk.

As illustrated in FIGS. 2A and 2B, the plurality of cell strings CS1a to CS2d may be connected in common to the string selection lines SSL1 to SSLk or may share the string selection lines SSL1 to SSLk. In this case, as the plurality of cell strings CS1a to CS2d are controlled by the same string selection line, a string selection transistor of an unselected cell string may be turned on during the read operation, the verify operation, or the channel recovery operation, thereby causing issues such as the reduction of reliability, the reduction of performance, and the increase in power consumption.

To solve the above issues, the string selection transistors SST1 to SSTk of the plurality of cell strings CS1a to CS2d may be connected to a string selection line in units of row such that the plurality of cell strings CS1a to CS2d are controlled individually or in units of row. In this case, the string selection transistor of the unselected cell string may be turned off during the read operation, the verify operation, or the channel recovery operation, and thus, the issues such as the reduction of reliability, the reduction of performance, and the increase in power consumption may be solved.

However, due to the physical limitation of the memory block BLKa, the structure in which the string selection transistors SST1 to SSTk of the plurality of cell strings CS1a to CS2d are connected to a string selection line in units of row may cause various issues. For example, the process (i.e., an SSL Cut process) of electrically separating string selection lines from each other by using string selection cuts may reduce a cell density due to a dummy hole and may increase the probability of occurrence of an additional defect during performing the process.

Meanwhile, the number of string selection lines may be limited in consideration of manufacturing costs (i.e., inescapable costs) of the memory block BLKa. In this case, by individually setting threshold voltages of the string selection transistors SST1 to SSTk of the plurality of cell strings CS1a to CS2d and controlling voltages to be applied to the plurality of string selection lines SSL1 to SSLK, the plurality of cell strings CS1a to CS2d may be individually controlled, and a maximum number of cell strings CS1a to CS2d may be controlled individually by using a minimum number of string selection lines SSL1 to SSLk.

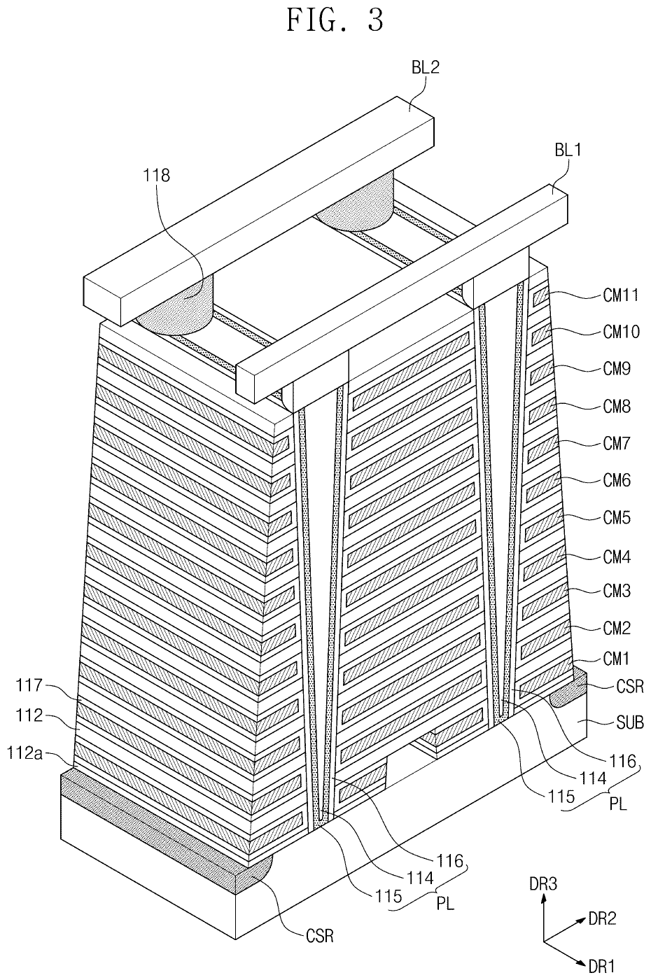

FIG. 3 is a cross-sectional view illustrating a partial structure of a memory block according to an embodiment of the present disclosure. Referring to FIGS. 1, 2A, 2B, and 3, there are provided common source regions CSR which extend along the first direction DR1 and are spaced apart from each other along the second direction DR2.

As an example, the common source regions CSR may be connected in common to form the common source line CSL (refer to FIG. 2A). As another example, the common source regions CSR may be physically or electrically separated from each other to form the common source lines CSLa, CSLb, CSLc, and CSLd (refer to FIG. 2B), respectively. In an embodiment, the substrate SUB may include a P-type semiconductor material. The common source regions CSR may include an N-type semiconductor material. For example, a conductive material for increasing the conductivity of the common source line CSL (refer to FIG. 2A) or CSLa, CSLb, CSLc, or CSLd (refer to FIG. 2B) may be disposed on the common source region CSR.

Between the common source regions CSR, insulating layers 112 and 112a are sequentially stacked on the substrate SUB along the third direction DR3 perpendicular to the substrate SUB. The insulating layers 112 and 112a may be stacked along the third direction DR3 so as to be spaced apart from each other. In an embodiment, the insulating layers 112 and 112a may include silicon oxide or silicon nitride. In an embodiment, the thickness of the insulating layer 112a (e.g., the thicknesses of the insulating layer 112a in the third direction DR3), which is in contact with the substrate SUB, from among the insulating layers 112 and 112a may be thinner than the thicknesses of each of the remaining insulating layers 112 (e.g., the thickness of each insulating layer in the third direction DR3).

Pillars PL may be disposed to be spaced apart from each other along the first direction DR1 and the second direction DR2 and may penetrate the insulating layers 112 and 112a along the third direction DR3. In an embodiment, the pillars PL may be in contact with the substrate SUB through the insulating layers 112 and 112a. Each of the pillars PL may include an inner material 114, a channel layer 115, and a first insulating layer 116.

The inner material 114 may include an insulating material or an air gap. The channel layer 115 may include a P-type semiconductor material or an intrinsic semiconductor material. The first insulating layer 116 may include one or more insulating layers (e.g., different insulating layers) such as a silicon oxide layer, a silicon nitride layer, and an aluminum oxide layer.

Between the common source regions CSR, second insulating layers 117 are provided on upper surfaces and lower surfaces of the insulating layers 112 and 112a and on exposed outer surfaces of the pillars PL. There may be removed the second insulating layers 117 provided on the upper surface of the uppermost insulating layer among the insulating layers 112 and 112a.

In each of the pillars PL, the first insulating layer 116 and the second insulating layer 117 may form an information storage layer when coupled adjacent to each other. For example, the first insulating layer 116 and the second insulating layer 117 may include oxide-nitride-oxide (ONO) or oxide-nitride-aluminum (ONA). The first insulating layer 116 and the second insulating layer 117 may form a tunneling insulating layer, a charge trap layer, and a blocking insulating layer.

Between the common source regions CSR and between and insulating layers 112 and 112a, conductive materials CM1 to CM11 are provided on exposed outer surfaces of the second insulating layers 117. The conductive materials CM1 to CM11 may include a metallic conductive material. Drains 118 are provided on the pillars PL. In an embodiment, the drains 118 may include an N-type semiconductor material (e.g., silicon). In an embodiment, the drains 118 may be in contact with the upper surfaces of the channel layers 115 of the pillars PL. FIG. 3 shows an example in which the number of conductive materials CM1 to CM11 is 11, but this is provided as an example, and the present disclosure is not limited thereto.

The first and second bit lines BL1 and BL2 which extend along the second direction DR2 and are spaced apart from each other along the first direction DR1 are provided on the drains 118. The first and second bit lines BL1 and BL2 are connected to the drains 118. In an embodiment, the drains 118 and the first and second bit lines BL1 and BL2 may be connected through contact plugs. The first and second bit lines BL1 and BL2 may include metallic conductive materials.

The pillars PL form the cell strings CS1a to CS1b and CS2a to CS2b together with the first and second insulating layers 116 and 117 and the conductive materials CM1 to CM11. Each of the pillars PL forms a cell string together with the first and second insulating layers 116 and 117 and the conductive materials CM1 to CM11 adjacent thereto.

The first conductive material CM1 may form the ground selection transistors GST together with the first and second insulating layers 116 and 117 and the channel layers 115. The first conductive material CM1 may extend in the first direction DR1 to form the ground selection lines GSLa, GSLb, GSLc, and GSLd.

The second to seventh conductive materials CM2 to CM7 may respectively form the first to sixth memory cells MC1 to MC6 together with the first and second insulating layers 116 and 117 and the channel layers 115, which are adjacent to each other. The second to seventh conductive materials CM2 to CM7 may extend along the first direction DR1 to form the first to sixth word lines WL1 to WL6, respectively.

The eighth to eleventh conductive materials CM8 to CM11 may form the string selection transistors SST1 to SST4 together with the first and second insulating layers 116 and 117 and the channel layers 115, which are adjacent to each other. The eighth to eleventh conductive materials CM8 to CM11 may extend along the first direction DR1 to form the first to fourth string selection lines SSL1 to SST4.

As the first to eleventh conductive materials CM1 to CM11 are stacked along the third direction DR3, in each cell string, the ground selection transistor GST, the memory cells MC1 to MC6, and the string selection transistors SST1 to SST4 may be stacked along the third direction DR3.

In each of the pillars PL, as the channel layer 115 is shared by the first to eleventh conductive materials CM1 to CM11, each cell string may be implemented such that the ground selection transistor GST, the memory cells MC1 to MC6, and the string selection transistors SST1 to SSS4 are serially connected along the third direction DR3. For example, the shared channel layer 115 may form a vertical body.

As the second to eleventh conductive materials CM2 to CM11 are connected in common, each of the word lines WL1 to WL6 and the string selection lines SSL1 to SSLA may be regarded as being connected in common to the cell strings CS1a to CS1b and CS2a to CS2b.

The memory block BLKa is provided at a three-dimensional (3D) memory array. The 3D memory array is monolithically formed in one or more physical levels of arrays of memory cells MC having an active area disposed above a silicon substrate and a circuitry associated with the operation of those memory cells MC. The circuitry associated with the operation of the memory cells MC may be located above or within a substrate. The term “monolithic” means that layers of each level of the array are directly deposited on the layers of each underlying level of the 3D memory array.

In an embodiment of the present disclosure, the 3D memory array includes vertical cell strings (or NAND strings) CS1a to CS1b and CS2a to CS2b which are vertically oriented such that at least one memory cell is located over another memory cell. The at least one memory cell may include a charge trap layer. Each cell string further includes at least one selection transistor placed on the memory cells MC. The at least one selection transistor may have the same structure as the memory cells MC and may be formed uniformly with the memory cells MC.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and the US Pat. Pub. No. 2011/0233648.

In FIGS. 2A, 2B, and 3, the common source region CSR is described as being formed at a portion of the substrate SUB. However, the common source region CSR may be implemented in the form of a plate covering the substrate SUB.

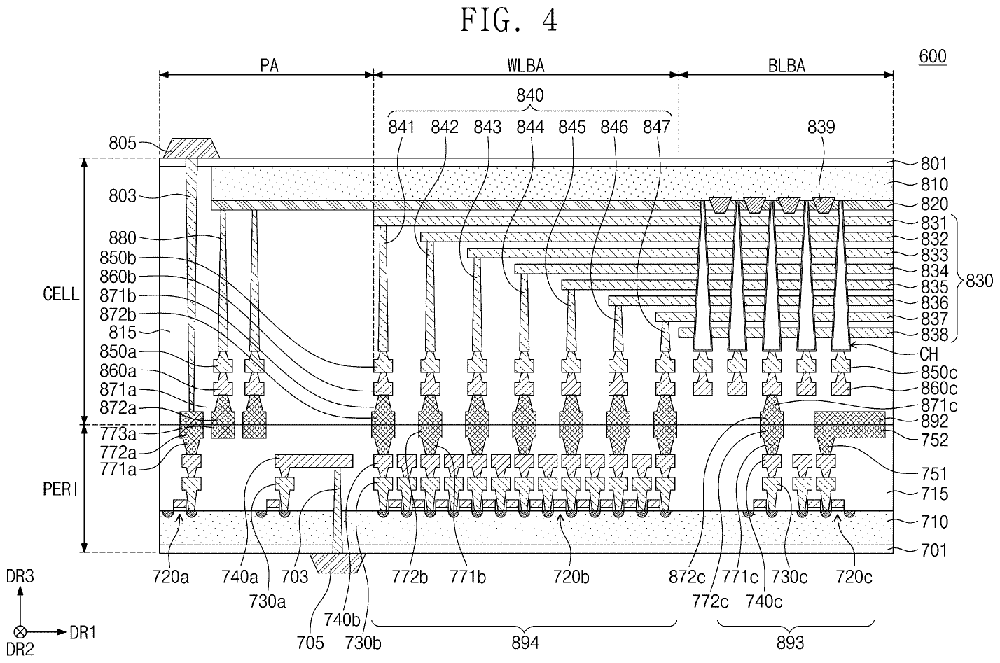

FIG. 4 is a view for describing a BVNAND structure that may be applied to a nonvolatile memory device according to an embodiment of the present disclosure. Referring to FIG. 4, a nonvolatile memory device 600 may have a chip to chip (C2C) structure. The C2C structure may mean that an upper chip including a cell region CELL is manufactured on a first wafer, a lower chip including a peripheral circuit region PERI is manufactured on a second wafer different from the first wafer, and then the upper chip and the lower chip are connected to each other by a bonding method. For example, the bonding method may mean a method of electrically connecting a bonding metal formed on an uppermost metal layer of the upper chip and a bonding metal formed on an uppermost metal layer of the lower chip. For example, when the bonding metal is formed of copper (Cu), the bonding method may be a Cu—Cu bonding method, and the bonding metal may be formed of aluminum or tungsten.

Each of the peripheral circuit region PERI and the cell region CELL of the nonvolatile memory device 600 may include an external pad bonding area PA, a word line bonding area WLBA, and a bit line bonding area BLBA. The peripheral circuit region PERI may include a first substrate 710, an interlayer insulating layer 715, a plurality of circuit elements 720a, 720b, and 720c formed on the first substrate 710, first metal layers 730a, 730b, and 730c connected to the plurality of circuit elements 720a, 720b, and 720c, and second metal layers 740a, 740b, and 740c formed on the first metal layers 730a, 730b, and 730c. In an embodiment, the first metal layers 730a, 730b, and 730c may be formed of tungsten having a relatively high resistance, and the second metal layers 740a, 740b, and 740c may be formed of copper having a relatively low resistance.

In the specification, only the first metal layers 730a, 730b, and 730c and the second metal layers 740a, 740b, and 740c are illustrated and described, but the present disclosure is not limited thereto, and at least one metal layer may be further formed on the second metal layers 740a, 740b, and 740c. At least some of one or more metal layers formed on the second metal layers 740a, 740b, and 740c may be formed of aluminum or the like having a lower resistance than that of copper forming the second metal layers 740a, 740b, and 740c.

The interlayer insulating layer 715 may be disposed on the first substrate 710 to cover the plurality of circuit elements 720a, 720b, and 720c, the first metal layers 730a, 730b, and 730c, and the second metal layers 740a, 740b, and 740c and may include an insulating material such as a silicon oxide or a silicon nitride.

Lower bonding metals 771b and 772b may be formed on the second metal layer 740b of the word line bonding area WLBA. In the word line bonding area WLBA, the lower bonding metals 771b and 772b of the peripheral circuit region PERI may be electrically connected to upper bonding metals 871b and 872b of the cell region CELL by the bonding method, and the lower bonding metals 771b and 772b and the upper bonding metals 871b and 872b may be formed of aluminum, copper, tungsten, or the like. The upper bonding metals 871b and 872b of the cell region CELL may be referred to as first metal pads, and the lower bonding metals 771b and 772b of the peripheral circuit region PERI may be referred to as second metal pads.

The cell region CELL may provide at least one memory block. The cell region CELL may include a second substrate 810 and a common source line 820. The common source line 820 may include a common source line cut (i.e., CSL Cut) structure 839. The common source line cut structure 839 may be inserted into the common source line 820 to generate a plurality of source lines physically or electrically separated from each other. A plurality of word lines 831 to 838 (hereinafter, collectively referred to as “830”) may be stacked on the second substrate 810 in a direction (e.g., Z-axis direction) perpendicular to an upper surface of the second substrate 810. String selection lines and ground selection lines may be arranged on and under the word lines 830, and the plurality of word lines 830 may be arranged between the string selection lines and the ground selection lines.

In the bit line bonding area BLBA, a channel structure CH may extend in the direction perpendicular to the upper surface of the second substrate 810 and pass through the word lines 830, the string selection lines, and the ground selection lines. The channel structure CH may include a data storage layer, a channel layer, a buried insulating layer, and the like, and the channel layer may be electrically connected to a first metal layer 850c and a second metal layer 860c. For example, the first metal layer 850c may be a bit line contact, and the second metal layer 860c may be a bit line. In an embodiment, the bit line may extend in a first direction (e.g., Y-axis direction) parallel to the upper surface of the second substrate 810.

In an embodiment illustrated in FIG. 4, an area in which the channel structure CH, the bit line, and the like are arranged may be defined as the bit line bonding area BLBA. The bit line may be electrically connected to the circuit elements 720c that provide a page buffer 893 in the peripheral circuit region PERI in the bit line bonding area BLBA. As an example, the bit line may be connected to upper bonding metals 871c and 872c in the cell region CELL, and the upper bonding metals 871c and 872c may be connected to lower bonding metals 771c and 772c connected to the circuit elements 720c of the page buffer 893.

In the word line bonding area WLBA, the word lines 830 may extend in a second direction (e.g., X-axis direction) parallel to the upper surface of the second substrate 810 and may be connected to a plurality of cell contact plugs 841 to 847 (hereinafter, collectively referred to as “840”). The word lines 830 and the cell contact plugs 840 may be connected to each other on pads in which at least some of the word lines 830 extend in the second direction (e.g., X-axis direction) by different lengths. A first metal layer 850b and a second metal layer 860b may be sequentially connected to upper portions of the cell contact plugs 840 connected to the word lines 830. The cell contact plugs 840 may be connected to the peripheral circuit region PERI through the upper bonding metals 871b and 872b in the cell region CELL and the lower bonding metals 771b and 772b in the peripheral circuit region PERI in the word line bonding area WLBA.

The cell contact plugs 840 may be electrically connected to the circuit elements 720b that provide a row decoder 894 in the peripheral circuit region PERI. In an embodiment, an operating voltage of the circuit elements 720b providing the row decoder 894 may be different from an operating voltage of the circuit elements 720c providing the page buffer 893. As an example, the operating voltage of the circuit elements 720c providing the page buffer 893 may be greater than the operating voltage of the circuit elements 720b providing the row decoder 894.

A common source line contact plug 880 may be disposed in the external pad bonding area PA. The common source line contact plug 880 may be formed of a conductive material such as a metal, a metal compound, or polysilicon and may be electrically connected to the common source line 820. A first metal layer 850a and a second metal layer 860a may be sequentially stacked on the common source line contact plug 880. As an example, an area in which the common source line contact plug 880, the first metal layer 850a, and the second metal layer 860a are arranged may be defined as the external pad bonding area PA.

Meanwhile, input/output pads 705 and 805 may be arranged in the external pad bonding area PA. Referring to FIG. 4, a lower insulating film 701 covering a lower surface of the first substrate 710 may be formed under the first substrate 710, and the first input/output pad 705 may be formed on the lower insulating film 701. The first input/output pad 705 may be connected to at least one of the plurality of circuit elements 720a, 720b, and 720c arranged in the peripheral circuit region PERI through a first input/output contact plug 703 and may be separated from the first substrate 710 by the lower insulating film 701. Further, a side insulating film may be disposed between the first input/output contact plug 703 and the first substrate 710 to electrically separate the first input/output contact plug 703 and the first substrate 710.

Referring to FIG. 4, an upper insulating layer 801 covering the upper surface of the second substrate 810 may be formed on the second substrate 810, and the second input/output pad 805 may be disposed on the upper insulating layer 801. The second input/output pad 805 may be connected to at least one of the plurality of circuit elements 720a, 720b, and 720c arranged in the peripheral circuit region PERI through a second input/output contact plug 803.

According to an embodiment, the second substrate 810, the common source line 820, and the like may not be arranged in an area in which the second input/output contact plug 803 is disposed. Further, the second input/output pad 805 may not overlap the word lines 830 in a third direction (e.g., Z-axis direction). Referring to FIG. 4, the second input/output contact plug 803 may be separated from the second substrate 810 in a direction parallel to the upper surface of the second substrate 810 and may be connected to the second input/output pad 805 through the interlayer insulating layer 815 of the cell region CELL.

According to an embodiment, the first input/output pad 705 and the second input/output pad 805 may be selectively formed. As an example, the nonvolatile memory device 600 may include only the first input/output pad 705 disposed on the first substrate 710 or only the second input/output pad 805 disposed on the second substrate 810. Alternatively, the nonvolatile memory device 600 may include both the first input/output pad 705 and the second input/output pad 805.

In the external pad bonding area PA and the bit line bonding area BLBA included in the cell region CELL and the peripheral circuit region PERI, a metal pattern of the uppermost metal layer may be present as a dummy pattern or the uppermost metal layer may be empty.

In the external pad bonding area PA, the nonvolatile memory device 600 may form a lower metal pattern 773a having the same shape as an upper metal pattern 872a of the cell region CELL on an uppermost metal layer of the peripheral circuit region PERI to correspond to the upper metal pattern 872a formed on an uppermost metal layer of the cell region CELL. The lower metal pattern 773a formed on the uppermost metal layer of the peripheral circuit region PERI may not be connected to a separate contact in the peripheral circuit region PERI. Similarly, in the external pad bonding area PA, an upper metal pattern having the same shape as the lower metal pattern of the peripheral circuit region PERI may be formed in an upper metal layer of the cell region CELL to correspond to the lower metal pattern formed on the uppermost metal layer of the peripheral circuit region PERI.

The lower bonding metals 771b and 772b may be formed on the second metal layer 740b of the word line bonding area WLBA. In the word line bonding area WLBA, the lower bonding metals 771b and 772b of the peripheral circuit region PERI may be electrically connected to the upper bonding metals 871b and 872b of the cell region CELL by the bonding method.

Further, in the bit line bonding area BLBA, an upper metal pattern 892 having the same shape as a lower metal pattern 752 of the peripheral circuit region PERI may be formed on the uppermost metal layer of the cell region CELL to correspond to the lower metal pattern 752 formed on the uppermost metal layer of the peripheral circuit region PERI. In an embodiment, no contact may be formed on the upper metal pattern 892 formed on the uppermost metal layer of the cell region CELL.

In an embodiment, a reinforced metal pattern having the same cross-sectional shape as the formed metal pattern may be formed on an uppermost metal layer of one of the cell region CELL and the peripheral circuit region PERI to correspond to the metal pattern formed on the uppermost metal layer of the other one of the cell region CELL and the peripheral circuit region PERI. No contact may be formed in the reinforced metal pattern.

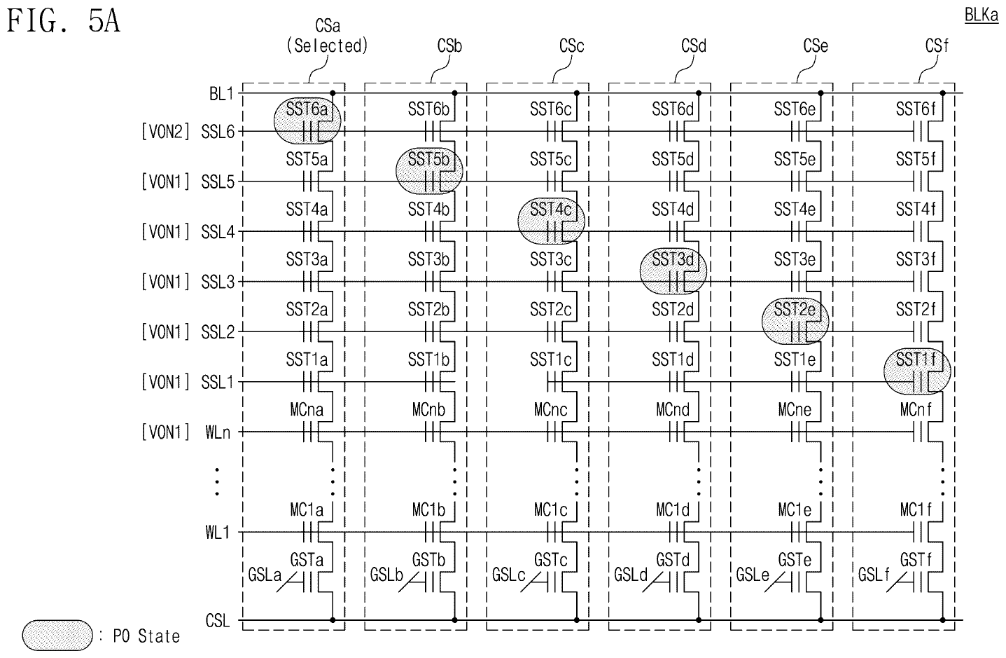

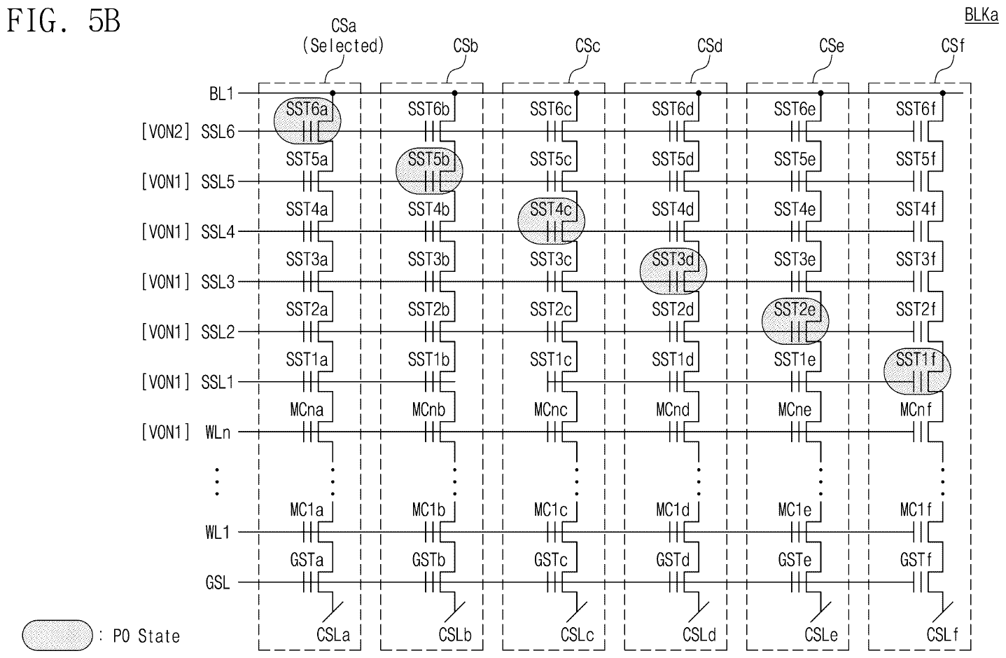

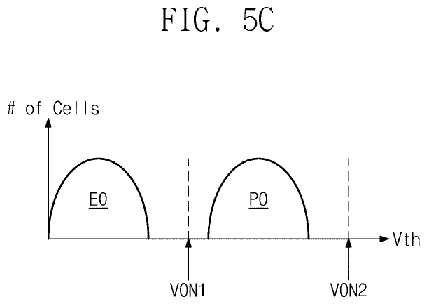

FIGS. 5A, 5B, and 5C are diagrams for describing a method of controlling a memory block, according to an embodiment of the present disclosure. Below, for convenience of description, embodiments of the present disclosure will be described based on a plurality of cell strings CSa, CSb, CSc, CSd, CSe, and CSf connected to the first bit line BL1. Also, some (e.g., dummy memory cells) of the cell transistors included in each of the plurality of cell strings CSa, CSb, CSc, CSd, CSe, and CSf are omitted. However, the present disclosure is not limited thereto.

Below, for brevity of drawing and for convenience of description, some string selection lines SSL and some string selection transistors SST are illustrated in a drawing, but the present disclosure is not limited thereto. For example, in the following drawings, string selection transistors or dummy string selection transistors are illustrated as being directly connected to the first bit line BL1, but additional string selection transistors may further exist between the illustrated string selection transistors and the first bit line BL1 or between the illustrated dummy string selection transistors and the first bit line BL1.

Below, for convenience of description, it is assumed that the memory block BLKa of FIG. 5A has a 1SSL-6GSL structure and the memory block BLKa of FIG. 5B has a 1SSL-6CSL structure. That is, the memory block BLKa of FIG. 5A may include six cell strings connected to one bit line BL1 and sharing the string selection lines SSL; in this case, the six cell strings may be respectively connected to individual ground selection lines. The memory block BLKa of FIG. 5B may include six cell strings connected to one bit line BL1 and sharing the string selection lines SSL; in this case, the six cell strings may be respectively connected to individual common source lines. However, the present disclosure is not limited thereto.

Referring to FIGS. 1 to 5A, the memory block BLKa may include the a-th to f-th cell strings CSa to CSf. Each of the a-th to f-th cell strings CSa to CSf may be connected between the first bit line BL1 and the common source line CSL. The a-th cell string CSa may include an a-th ground selection transistor GSTa, a plurality of memory cells MC1a to MCna, and a plurality of string selection transistors SST1a to SST6a. The b-th cell string CSb may include a b-th ground selection transistor GSTb, a plurality of memory cells MC1b to MCnb, and a plurality of string selection transistors SST1b to SST6b. The c-th cell string CSc may include a c-th ground selection transistor GSTc, a plurality of memory cells MC1c to MCnc, and a plurality of string selection transistors SST1c to SST6c. The d-th cell string CSd may include a d-th ground selection transistor GSTd, a plurality of memory cells MC1d to MCnd, and a plurality of string selection transistors SST1d to SST6d. The e-th cell string CSe may include an e-th ground selection transistor GSTe, a plurality of memory cells MC1e to MCne, and a plurality of string selection transistors SST1e to SST6e. The f-th cell string CSf may include a f-th ground selection transistor GSTf, a plurality of memory cells MC1f to MCnf, and a plurality of string selection transistors SST1f to SST6f.

The ground selection transistor GSTa of the a-th cell string CSa may be connected to an a-th ground selection line GSLa; the ground selection transistor GSTb of the b-th cell string CSb may be connected to a b-th ground selection line GSLb; the ground selection transistor GSTc of the c-th cell string CSc may be connected to a c-th ground selection line GSLc; the ground selection transistor GSTd of the d-th cell string CSd may be connected to a d-th ground selection line GSLd; the ground selection transistor GSTe of the e-th cell string CSe may be connected to an e-th ground selection line GSLe; and, the ground selection transistor GSTf of the f-th cell string CSf may be connected to an f-th ground selection line GSLf.

The string selection transistors SST1a to SST6a, SST1b to SST6b, SST1c to SST6c, SST1d to SST6d, SST1e to SST6e, and SST1f to SST6f and the memory cells MC1a to MCna, MC1b to MCnb, MC1c to MCnc, MC1d to MCnd, MC1e to MCne, and MC1f to MCnf of the a-th to f-th cell strings CSa to CSf may be connected to a plurality of string selection lines SSL1 to SSL6 and a plurality of word lines WL1 to WLn. For example, the first memory cells MC1a, MC1b, MC1c, MC1d, MC1e, and MC1f of the a-th to f-th cell strings CSa to CSf may be connected to the first word line WL1, and the n-th memory cells MCna, MCnb, MCnc, MCnd, MCne, and MCnf of the a-th to f-th cell strings CSa to CSf may be connected to the n-th word line WLn.

The string selection transistors SST1a, SST1b, SST1c, SST1d, SST1e, and SST1f of the a-th to f-th cell strings CSa to CSf may be connected to a first string selection line SSL1; the string selection transistors SST2a, SST2b, SST2c, SST2d, SST2e, and SST2f of the a-th to f-th cell strings CSa to CSf may be connected to a second string selection line SSL2; the string selection transistors SST3a, SST3b, SST3c, SST3d, SST3e, and SST3f of the a-th to f-th cell strings CSa to CSf may be connected to a third string selection line SSL3; the string selection transistors SST4a, SST4b, SST4c, SST4d, SST4e, and SST4f of the a-th to f-th cell strings CSa to CSf may be connected to a fourth string selection line SSLA; the string selection transistors SST5a, SST5b, SST5c, SST5d, SST5e, and SST5f of the a-th to f-th cell strings CSa to CSf may be connected to a fifth string selection line SSL5; and, the string selection transistors SST6a, SST6b, SST6c, SST6d, SST6e, and SST6f of the a-th to f-th cell strings CSa to CSf may be connected to a sixth string selection line SSL6.

In an embodiment, while the nonvolatile memory device 100 operates, one of the a-th to f-th cell strings CSa to CSf may be selected, and the remaining cell strings thereof may not be selected. In this case, a threshold voltage of each of the plurality of string selection transistors SST1a to SST6f may be set such that the remaining unselected cell strings among the plurality of cell strings CSa to CSf other than the selected cell string are not electrically connected to the first bit line BL1.

For example, as illustrated in FIG. 5C, a threshold voltage or a threshold voltage distribution of a 0-th program state P0 may be higher than a threshold voltage or a threshold voltage distribution of a 0-th erase state E0. In this case, a string selection transistor having the 0-th program state P0 may be turned off by a first on-voltage VON1 and may be turned on by a second on-voltage VON2. A string selection transistor having the 0-th erase state E0 may be turned on by the first on-voltage VON1 and may be turned on by the second on-voltage VON2.

In an embodiment, the threshold voltage distribution of the 0-th erase state E0 may be different from the threshold voltage distribution of the 0-th program state P0. The threshold voltage distribution of the 0-th erase state E0 may be lower than the threshold voltage distribution of the 0-th program state P0. For example, threshold voltages of string selection transistors corresponding to the 0-th erase state E0 may be lower than threshold voltages of string selection transistors corresponding to the 0-th program state P0. In an embodiment, the threshold voltages of the string selection transistors corresponding to the 0-th erase state E0 may be different from threshold voltages of erased memory cells MC.

The 6a-th 5b-th, 4c-th, 3d-th, 2e-th, and 1f-th string selection transistors SST6a, SST5b, SST4c, SST3d, SST2e, and SST1f among the plurality of string selection transistors SST1a to GST6f may be set to the 0-th program state P0. In this case, by applying the first and second on-voltages VON1 and VON2 to the plurality of string selection lines SSL1 to SSL6, the remaining unselected cell strings among the plurality of cell strings CSa to CSf other than the selected cell string may not be electrically connected to the first bit line BL1.

In detail, it is assumed that the a-th cell string CSa is a selected cell string. In this case, a first voltage V1 may be applied to the a-th ground selection line GSLa, and an off voltage VOFF may be applied to the remaining ground selection lines GSLb, GSLc, GSLd, GSLe, and GSLf. According to the above condition, the a-th ground selection transistor GSTa of the a-th cell string CSa may be turned on, and the ground selection transistors GSTb, GSTc, GSTd, GSTe, and GSTf of the remaining cell strings CSb, CSc, CSd, CSe, and CSf may be turned off.

In this case, the first on-voltage VON1 may be applied to the first to fifth string selection line lines SSL1 to SSL5, and the second on-voltage VON2 may be applied to the sixth string selection line SSL6. As the first on-voltage VON1 is applied to the first string selection line SSL1, the 1a-th, 1b-th, 1c-th, 1d-th and 1e-th, string selection transistors SST1a, SST1b, SST1c, SST1d, and SST1e may be turned on, and the 1f-th string selection transistor SST1f may be turned off. As the first on-voltage VON1 is applied to the second string selection line SSL2, the 2a-th, 2b-th, 2c-th, 2d-th, and 2f-th string selection transistors SST2a, SST2b, SST2c, SST2d, and SST2f may be turned on, and the 2e-th string selection transistor SST2e may be turned off. As the first on-voltage VON1 is applied to the third string selection line SSL3, the 3a-th, 3b-th, 3c-th, 3e-th, and 3f-th string selection transistors SST3a, SST3b, SST3c, SST3e, and SST3f may be turned on, and the 3d-th string selection transistor SST3d may be turned off. As the first on-voltage VON1 is applied to the fourth string selection line SSL4, the 4a-th, 4b-th, 4d-th, 4e-th and 4f-th string selection transistors SST4a, SST4b, SST4d, SST4e, and SST4f may be turned on, and the 4c-th string selection transistor SST4c may be turned off. As the first on-voltage VON1 is applied to the fifth string selection line SSL5, the 5a-th, 5c-th, 5d-th, 5e-th, and 5f-th string selection transistors SST5a, SST5c, SST5d, SST5e, and SST5f may be turned on, and the 5b-th string selection transistor SST5b may be turned off. As the second on-voltage VON2 is applied to the sixth string selection line SSL6, the string selection transistors SST6a, SST6b, SST6c, SST6d, SST6e, and SST6f connected to the sixth string selection line SSL6 may be turned on.

That is, according to the above bias condition associated with the string selection lines SSL1 to SSL6, because all the string selection transistors SST1a to SST6a of the a-th cell string CSa being the selected cell string are turned on, the a-th cell string CSa may be electrically connected to the first bit line BL1. In contrast because the 5b-th, 4c-th, 3d-th, 2e-th, and 1f-th string selection transistors SST5b, SST4c, SST3d, SST2e, and SST1f are turned off, the b-th, c-th, d-th, e-th, and f-th cell strings CSb, CSc, CSd, CSe, and CSf being the unselected cell strings may be electrically separated from the first bit line BL1. Accordingly, the issues, which occur during the operation of the nonvolatile memory device 100, such as the reduction of reliability, the reduction of performance, and the increase in power consumption may be prevented. Also, because the string selection line cut process (i.e., SSL Cut process) is not introduced in the process of manufacturing the nonvolatile memory device 100, the issues such as the reduction of cell density and the increase in probability of occurrence of an additional defect may be prevented.

Referring to FIGS. 1, 4, and 5B, as described above, the memory block BLKa of FIG. 5B may be implemented to be the same as the memory block BLKa of FIG. 5A except that the six cell strings CSa to CSf connected to one bit line BL1 and sharing the string selection lines SSL are respectively connected to six common source lines CSLa to CSLf. Thus, additional description will be omitted to avoid redundancy.

In an embodiment, to reduce costs (i.e., inescapable costs) necessary in the process of manufacturing the memory block BLKa, a sufficient number of string selection lines SSL or string selection transistors SST may not be formed in the memory block BLKa. For example, in the memory block BLKa described with reference to FIGS. 5A and 5B, the number of string selection lines SSL may be equal to the number of cell strings CS capable of being controlled individually, but the string selection lines SSL, the number of which is equal to the number of cell strings CS, may not be formed to reduce the manufacturing costs (i.e., inescapable costs). In this case, the cell strings CS may not be controlled individually as intended, and the reliability and performance of the nonvolatile memory device 100 may be reduced.

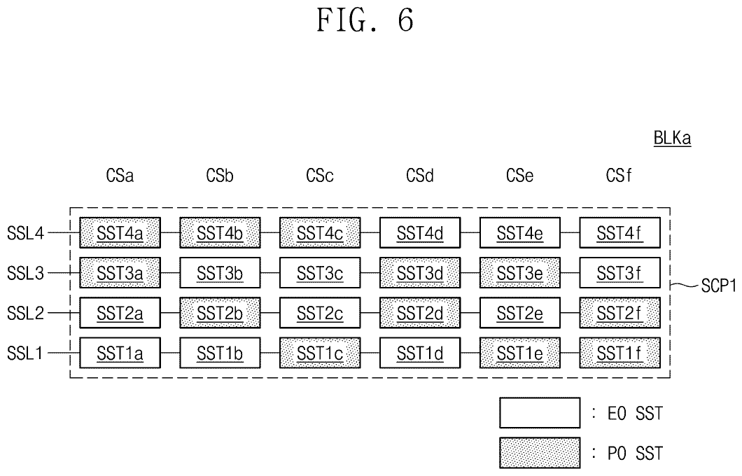

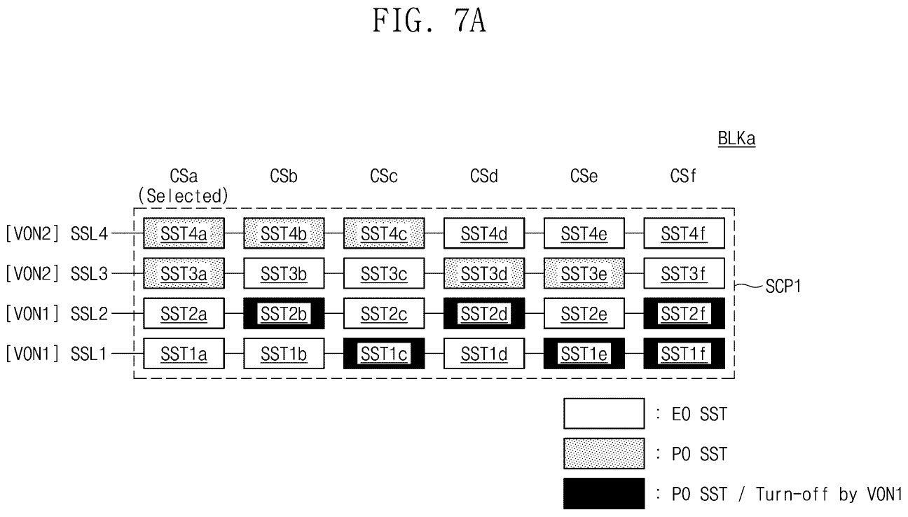

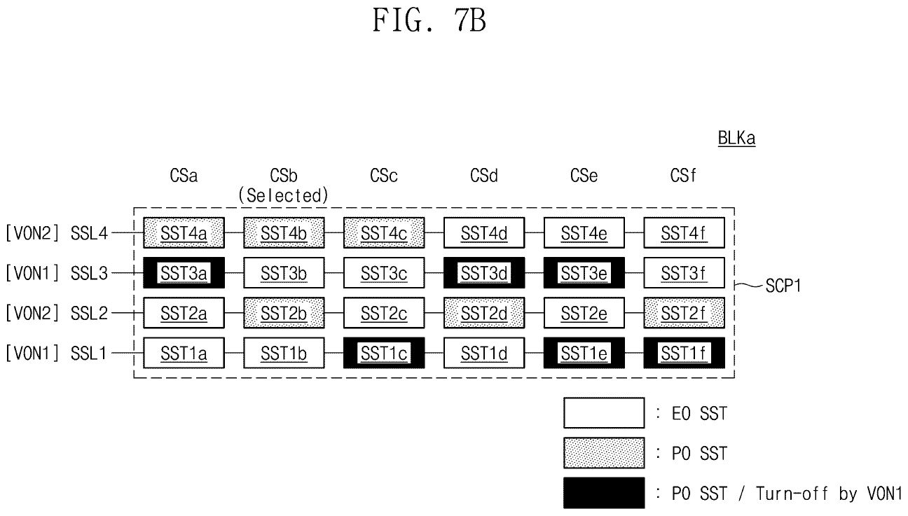

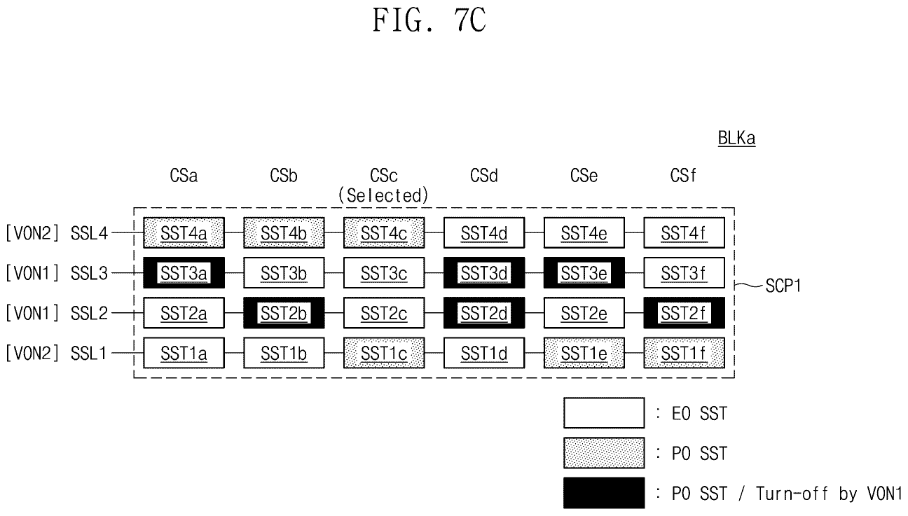

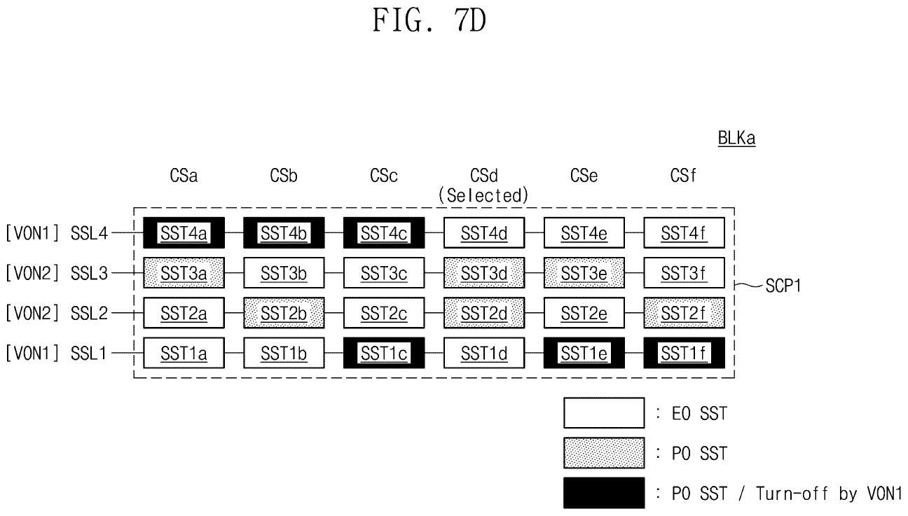

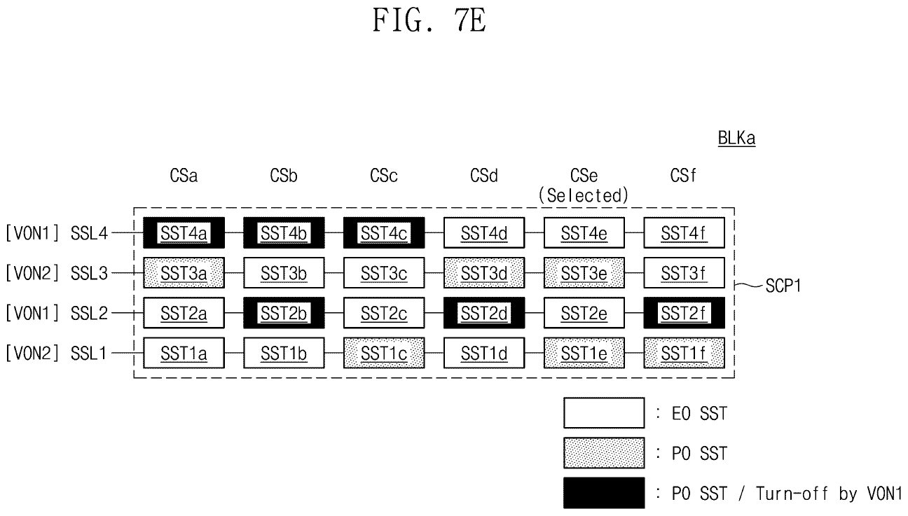

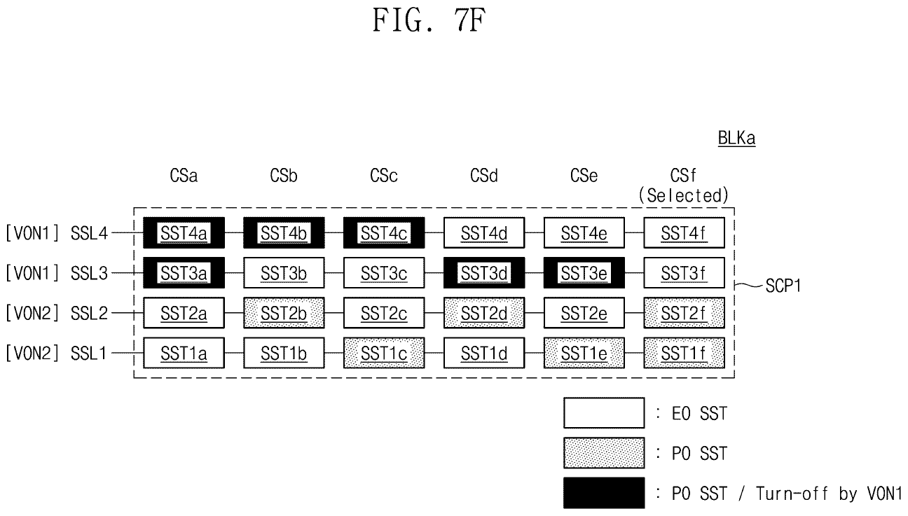

FIG. 6 is a diagram illustrating a string selection transistor coding pattern of string selection transistors of a memory block according to an embodiment of the present disclosure. FIGS. 7A to 7F are diagrams for describing an operation of a memory block including string selection transistors programmed depending on the string selection transistor coding pattern of FIG. 6.

Below, for brevity of drawing, a string selection transistor (SST) coding pattern (SCP) corresponding to string selection transistors of the memory block BLKa is illustrated. However, the present disclosure is not limited thereto. For example, it may be understood that the string selection transistors of the nonvolatile memory device 100 have threshold voltages corresponding to a string selection transistor coding pattern to be described with reference to the following drawings and the string selection transistors are applicable to the memory block BLKa or the nonvolatile memory device 100 described above.

First, referring to FIGS. 1, 6, 7A, 7B, 7C, 7D, 7E, and 7F, the memory block BLKa may include the first to fourth string selection lines SSL1 to SSLA and the a-th to f-th cell strings CSa to CSf. The a-th cell string CSa may include a plurality of string selection transistors SST1a to SST4a, the b-th cell string CSb may include a plurality of string selection transistors SST1b to SST4b, the c-th cell string CSc may include a plurality of string selection transistors SST1c to SST4c, the d-th cell string CSd may include a plurality of string selection transistors SST1d to SST4d, the e-th cell string CSe may include a plurality of string selection transistors SST1e to SST4e, and the f-th cell string CSf may include a plurality of string selection transistors SST1f to SST4f.

In an embodiment, as described above, each of the a-th to f-th cell strings CSa to CSf may further include at least one ground selection transistor GST, a plurality of memory cells MC, and at least one dummy memory cell dMC.

The string selection transistors SST1a, SST1b, SST1c, SST1d, SST1e, and SST1f of the a-th to f-th cell strings CSa to CSf may be connected to the first string selection line SSL1; the string selection transistors SST2a, SST2b, SST2c, SST2d, SST2e, and SST2f of the a-th to f-th cell strings CSa to CSf may be connected to the second string selection line SSL2; the string selection transistors SST3a, SST3b, SST3c, SST3d, SST3e, and SST3f of the a-th to f-th cell strings CSa to CSf may be connected to the third string selection line SSL3; and, the string selection transistors SST4a, SST4b, SST4c, SST4d, SST4e, and SST4f of the a-th to f-th cell strings CSa to CSf may be connected to the fourth string selection line GSLA.

The string selection transistors SST1a to SST4f connected to the first to fourth string selection lines SSL1 to SSL4 may be programmed based on a first SST coding pattern SCP1. For example, the first SST coding pattern SCP1 may refer to information indicating threshold voltage states (e.g., the 0-th erase state E0 and the 0-th program state P0) of the string selection transistors SST1a to SST4f.

When the string selection transistors SST1a to SST4f are programmed based on the first SST coding pattern SCP1, the 3a-th, 4a-th, 2b-th, 4b-th, 1c-th, 4c-th, 2d-th, 3d-th, 1e-th, 3e-th, 1f-th, and 2f-th string selection transistors SST3a, SST4a, SST2b, SST4b, SST1c, SST4c, SST2d, SST3d, SST1e, SST3e, SST1f, and SST2f may have the 0-th program state P0, and the remaining string selection transistors SST1a, SST2a, SST1b, SST3b, SST2c, SST3c, SST1d, SST4d, SST2e, SST4e, SST3f, and SST4f may have the 0-th erase state E0.

When the string selection transistors SST1a to SST4f are programmed as illustrated in FIG. 6, it may be possible to individually control cell strings based on string selection lines, the number of which is less than the number of cell strings.

For example, as illustrated in FIG. 7A, it is assumed that the a-th cell string CSa is a selected cell string. In this case, according to the first SST coding pattern SCP1, because the 1a-th and 2a-th string selection transistors SST1a and SST2a of the a-th cell string CSa are in the 0-th erase state E0 and the remaining string selection transistors SST3a and SST4a are in the 0-th program state P0, the first on-voltage VON1 may be applied to the first and second string selection lines SSL1 and SSL2, and the second on-voltage VON2 may be applied to the remaining string selection lines SSL3 and SSL4.

According to the bias condition of the string selection lines SSL1 to SSLA of FIG. 7A, the string selection transistors SST1a to SST4a of the a-th cell string CSa may be turned on. The 1c-th string selection transistor SST1c of the c-th cell string CSc, the 1e-th string selection transistor SST1e of the e-th cell string CSe, and the 1f-th string selection transistor SST1f of the f-th cell string CSf may be turned off by the first on-voltage VON1 of the first string selection line SSL1. The 2b-th string selection transistor SST2b of the b-th cell string CSb, the 2d-th string selection transistor SST2d of the d-th cell string CSd, and the 2f-th string selection transistor SST2f of the f-th cell string CSf may be turned off by the first on-voltage VON1 of the second string selection line SSL2.

As illustrated in FIG. 7A, when the a-th cell string CSa is the selected cell string, in each of the b-th, c-th, d-th, e-th, and f-th cell strings CSb, CSc, CSd, CSe, and CSf being unselected cell strings, at least one string selection transistor may be turned off. Accordingly, the a-th cell string CSa may be individually controlled.

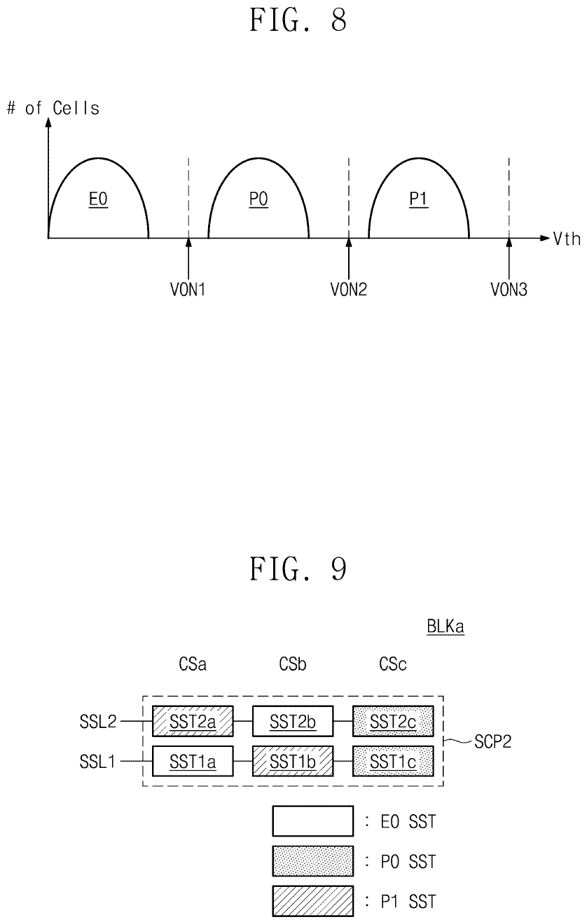

As another perspective on FIGS. 6 and 7A, the control signals of the string select lines take on binary values (VON1 or VON2, FIG. 8 uses more than two values.). As an illustration of four string select lines controlling six cell strings, consider the sixteen binary 4-tuples which count from “0000” to “1111.” The value “0” or “1” in the 4-tuple corresponds to a control signal being VON2 or VON1, respectively. Two transistors in P0 must be turned on for a string select line to be selected. See FIG. 6. There are six 4-tuples of the sixteen which qualify for this task: {0011, 0101, 0110, 1001, 1010, 1100}. These may be mapped to {CSa, CSb, CSd, CSc, CSe, and CSf} using the pattern {SSL1, SSL2, SSL3, SSL4}.

Next, as illustrated in FIG. 7B, it is assumed that the b-th cell string CSb is a selected cell string. In this case, according to the first SST coding pattern SCP1, because the 1b-th and 3b-th string selection transistors SST1b and SST3b of the b-th cell string CSb are in the 0-th erase state E0 and the remaining string selection transistors SST2b and SST4b are in the 0-th program state P0, the first on-voltage VON1 may be applied to the first and third string selection lines SSL1 and SSL3, and the second on-voltage VON2 may be applied to the remaining string selection lines SSL2 and SSL4.

According to the bias condition of the string selection lines SSL1 to SSLA of FIG. 7B, the string selection transistors SST1b to SST4b of the b-th cell string CSb may be turned on. The 1c-th string selection transistor SST1c of the c-th cell string CSc, the 1e-th string selection transistor SST1e of the e-th cell string CSe, and the 1f-th string selection transistor SST1f of the f-th cell string CSf may be turned off by the first on-voltage VON1 of the first string selection line SSL1. The 3a-th string selection transistor SST3a of the a-th cell string CSa, the 3d-th string selection transistor SST3d of the d-th cell string CSd, and the 3e-th string selection transistor SST3e of the e-th cell string CSe may be turned off by the first on-voltage VON1 of the third string selection line SSL3.

As illustrated in FIG. 7B, when the b-th cell string CSb is a selected cell string, in each of the a-th, c-th, d-th, e-th, and f-th cell strings CSa, CSc, CSd, CSe, and CSf being unselected cell strings, at least one string selection transistor may be turned off. Accordingly, the b-th cell string CSb may be individually controlled.

Next, as illustrated in FIG. 7C, it is assumed that the c-th cell string CSc is a selected cell string. In this case, according to the first SST coding pattern SCP1, because the 2c-th and 3c-th string selection transistors SST2c and SST3c of the c-th cell string CSc are in the 0-th erase state E0 and the remaining string selection transistors SST1c and SST4c are in the 0-th program state P0, the first on-voltage VON1 may be applied to the second and third string selection lines SSL2 and SSL3, and the second on-voltage VON2 may be applied to the remaining string selection lines SSL1 and SSL4.

According to the bias condition of the string selection lines SSL1 to SSLA of FIG. 7C, the string selection transistors SST1c to SST4c of the c-th cell string CSc may be turned on. The 2b-th string selection transistor SST2b of the b-th cell string CSb, the 2d-th string selection transistor SST2d of the d-th cell string CSd, and the 2f-th string selection transistor SST2f of the f-th cell string CSf may be turned off by the first on-voltage VON1 of the second string selection line SSL2. The 3a-th string selection transistor SST3a of the a-th cell string CSa, the 3d-th string selection transistor SST3d of the d-th cell string CSd, and the 3e-th string selection transistor SST3e of the e-th cell string CSe may be turned off by the first on-voltage VON1 of the third string selection line SSL3.

As illustrated in FIG. 7C, when the c-th cell string CSc is a selected cell string, in each of the a-th, b-th, d-th, e-th, and f-th cell strings CSa, CSb, CSd, CSe, and CSf being unselected cell strings, at least one string selection transistor may be turned off. Accordingly, the c-th cell string CSc may be individually controlled.

Then, as illustrated in FIG. 7D, it is assumed that the d-th cell string CSd is a selected cell string. In this case, according to the first SST coding pattern SCP1, because the 1d-th and 4d-th string selection transistors SST1d and SST4d of the d-th cell string CSd are in the 0-th erase state E0 and the remaining string selection transistors SST2d and SST3d are in the 0-th program state P0, the first on-voltage VON1 may be applied to the first and fourth string selection lines SSL1 and SSL4, and the second on-voltage VON2 may be applied to the remaining string selection lines SSL2 and SSL3.

According to the bias condition of the string selection lines SSL1 to SSLA of FIG. 7D, the string selection transistors SST1d to SST4d of the d-th cell string CSd may be turned on. The 1c-th string selection transistor SST1c of the c-th cell string CSc, the 1e-th string selection transistor SST1e of the e-th cell string CSe, and the 1f-th string selection transistor SST1f of the f-th cell string CSf may be turned off by the first on-voltage VON1 of the first string selection line SSL1. The 4a-th string selection transistor SST4a of the a-th cell string CSa, the 4b-th string selection transistor SST4b of the b-th cell string CSb, and the 4c-th string selection transistor SST4c of the c-th cell string CSc may be turned off by the first on-voltage VON1 of the fourth string selection line SSL4.

As illustrated in FIG. 7D, when the d-th cell string CSd is a selected cell string, in each of the a-th, b-th, c-th, e-th, and f-th cell strings CSa, CSb, CSc, CSe, and CSf being unselected cell strings, at least one string selection transistor may be turned off. Accordingly, the d-th cell string CSd may be individually controlled.

Then, as illustrated in FIG. 7E, it is assumed that the e-th cell string CSe is a selected cell string. In this case, according to the first SST coding pattern SCP1, because the 2e-th and 4e-th string selection transistors SST2e and SST4e of the e-th cell string CSe are in the 0-th erase state E0 and the remaining string selection transistors SST1e and SST3e are in the 0-th program state P0, the first on-voltage VON1 may be applied to the second and fourth string selection lines SSL2 and SSL4, and the second on-voltage VON2 may be applied to the remaining string selection lines SSL1 and SSL3.

According to the bias condition of the string selection lines SSL1 to SSL4 of FIG. 7E, the string selection transistors SST1e to SST4e of the e-th cell string CSe may be turned on. The 2b-th string selection transistor SST2b of the b-th cell string CSb, the 2d-th string selection transistor SST2d of the d-th cell string CSd, and the 2f-th string selection transistor SST2f of the f-th cell string CSf may be turned off by the first on-voltage VON1 of the second string selection line SSL2. The 4a-th string selection transistor SST4a of the a-th cell string CSa, the 4b-th string selection transistor SST4b of the b-th cell string CSb, and the 4c-th string selection transistor SST4c of the c-th cell string CSc may be turned off by the first on-voltage VON1 of the fourth string selection line SSLA.

As illustrated in FIG. 7E, when the e-th cell string CSe is a selected cell string, in each of the a-th, b-th, c-th, d-th, and f-th cell strings CSa, CSb, CSc, CSd, and CSf being unselected cell strings, at least one string selection transistor may be turned off. Accordingly, the e-th cell string CSe may be individually controlled.

Then, as illustrated in FIG. 7F, it is assumed that the f-th cell string CSf is a selected cell string. In this case, according to the first SST coding pattern SCP1, because the 3f-th and 4f-th string selection transistors SST3f and SST4f of the f-th cell string CSf are in the 0-th erase state E0 and the remaining string selection transistors SST1f and SST2f are in the 0-th program state P0, the first on-voltage VON1 may be applied to the third and fourth string selection lines SSL3 and SSL4, and the second on-voltage VON2 may be applied to the remaining string selection lines SSL1 and SSL2.

According to the bias condition of the string selection lines SSL1 to SSLA of FIG. 7F, the string selection transistors SST1f to SST4f of the f-th cell string CSf may be turned on. The 3a-th string selection transistor SST3a of the a-th cell string CSa, the 3d-th string selection transistor SST3d of the d-th cell string CSd, and the 3e-th string selection transistor SST3e of the e-th cell string CSe may be turned off by the first on-voltage VON1 of the third string selection line SSL3. The 4a-th string selection transistor SST4a of the a-th cell string CSa, the 4b-th string selection transistor SST4b of the b-th cell string CSb, and the 4c-th string selection transistor SST4c of the c-th cell string CSc may be turned off by the first on-voltage VON1 of the fourth string selection line SSLA.

As illustrated in FIG. 7F, when the f-th cell string CSf is a selected cell string, in each of the a-th, b-th, c-th, d-th, and e-th cell strings CSa, CSb, CSc, CSd, and CSe being unselected cell strings, at least one string selection transistor may be turned off. Accordingly, the f-th cell string CSf may be individually controlled.

In FIGS. 6 to 7F, the operation of individually controlling the six cell strings CSa to CSf based on the four string selection lines SSL1 to SSL4 is described based on the memory block BLKa based on a string selection transistor (i.e., 2-stage SST) having the 0-th erase state E0 or the 0-th program state P0, but the present disclosure is not limited thereto. For example, in the memory block BLKa based on the 2-stage SST, the number of cell strings which are capable of being individually controlled based on the four string selection lines SSL1 to SSLA may be calculated based on Equation 1 below.

$$n = C ( m , [ m / 2 ] ) \qquad [ Equation 1 ]$$

In Equation 1 above, in the memory block BLKa based on the 2-stage SST, “m” indicates the number of string selection lines, and “n” indicates the number of cell strings capable of being individually controlled based on the “m” string selection lines. Herein, for integers x and y greater than or equal to 0, C (x, y) is a function indicating the number of cases of combining y out of x, and [x] is a function indicating the largest integer not greater than x.

Referring to Equation 1, “n” cell strings may respectively correspond to different combinations in which (m/2) string selection transistors among the “m” string selection transistors have the 0-th erase state E0 and the remaining string selection transistors have the 0-th program state P0. Accordingly, in FIGS. 6 to 7F, because the number of string selection lines is four (i.e., m=4), the number of cell strings capable of being individually controlled may be six (i.e., n=6).

In particular, when “m” is an odd number of 3 or more, the “n” cell strings may respectively correspond to different combinations in which ((m/2)+1) string selection transistors among the “m” string selection transistors have the 0-th erase state E0 and the remaining string selection transistors have the 0-th program state P0. Accordingly, when the number of string selection lines is five (i.e., m=5), the number of cell strings capable of being individually controlled may be the number of different combinations in which two (=[5/2]) string selection transistors among the five string selection transistors have the 0-th erase state E0, that is, C (5, 2)=10. Also, when the number of string selection lines is five (i.e., m=5), the number of cell strings capable of being individually controlled may be the number of different combinations in which three (=[5/2]+1) string selection transistors among the five string selection transistors have the 0-th erase state E0, that is, C (5, 3)=10. That is, the SST coding pattern for individually controlling an identical number of cell strings based on an identical number of string selection lines may be variously implemented.

FIG. 8 is a diagram for describing a method of controlling a memory block, according to an embodiment of the present disclosure. In FIG. 8, the horizontal axis represents a threshold voltage Vth, and the vertical axis represents the number of memory cells.

In FIGS. 5A to 7F, the description is given as a string selection transistor has the 0-th erase state E0 or the 0-th program state P0 (i.e., the 2-stage SST), but the present disclosure is not limited thereto. For example, the string selection transistor may have one of a plurality of threshold voltages and may be turned on or turned off in response to a voltage level corresponding to the threshold voltage.

Referring to FIG. 8, the string selection transistor may have the 0-th erase state E0, the 0-th program state P0, or the first program state P1. That is, the string selection transistor may be a 3-stage SST.

For example, a first string selection transistor may have a first threshold voltage, a second string selection transistor may have a second threshold voltage higher than the first threshold voltage, and a third string selection transistor may have a third threshold voltage higher than the second threshold voltage. In this case, the first string selection transistor may be turned on by a first voltage higher than the first threshold voltage and lower than the second and third threshold voltages, and the second and third string selection transistors may be turned off by the first voltage. The first and second string selection transistors may be turned on by a second voltage higher than the first and second threshold voltages and lower than the third threshold voltage, and the third string selection transistor may be turned off by the second voltage. The first, second, and third string selection transistors may be turned on by a third voltage higher than the third threshold voltage. As described above, each of the string selection transistors may have one of the plurality of threshold voltages and may be turned on or turned off in response to a voltage applied to the corresponding string selection line.

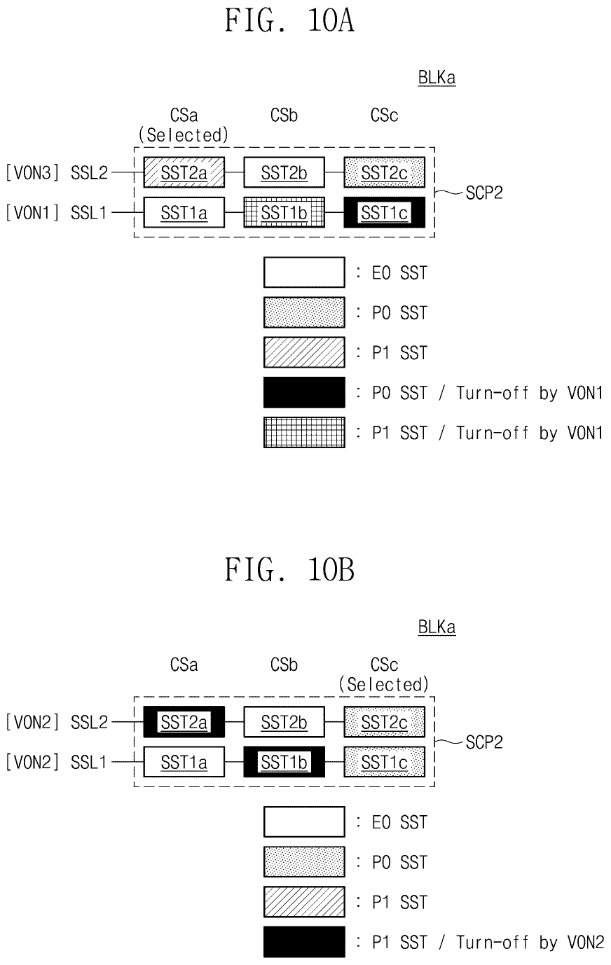

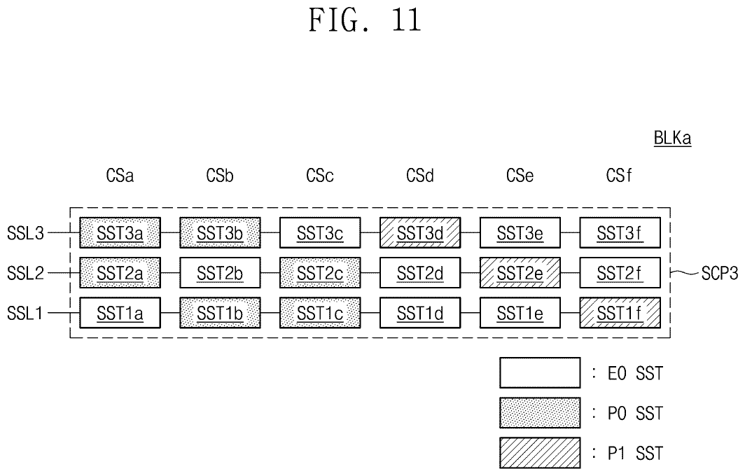

FIG. 9 is a diagram illustrating a string selection transistor coding pattern of string selection transistors of a memory block according to an embodiment of the present disclosure. FIGS. 10A and 10B are diagrams for describing an operation of a memory block including string selection transistors programmed depending on the string selection transistor coding pattern of FIG. 9.

First, referring to FIGS. 1, 8, 9, 10A, and 10B, the memory block BLKa may include the first and second string selection lines SSL1 and SSL2 and the a-th to c-th cell strings CSa to CSc. The a-th cell string CSa may include a plurality of string selection transistors SST1a and SST2a, the b-th cell string CSb may include a plurality of string selection transistors SST1b and SST2b, and the c-th cell string CSc may include a plurality of string selection transistors SST1c and SST2c.

In an embodiment, as described above, each of the a-th to c-th cell strings CSa to CSc may further include at least one ground selection transistor GST, a plurality of memory cells MC, and at least one dummy memory cell dMC.

The string selection transistors SST1a, SST1b, and SST1c of the a-th to c-th cell strings CSa to CSc may be connected to the first string selection line SSL1, and the string selection transistors SST2a, SST2b, and SST2c of the a-th to c-th cell strings CSa to CSc may be connected to the second string selection line SSL2.

The string selection transistors SST1a to SST2c connected to the first and second string selection lines SSL1 and SSL2 may be programmed based on a second SST coding pattern SCP2. For example, the second SST coding pattern SCP2 may refer to information indicating threshold voltage states (e.g., the 0-th erase state E0, the 0-th program state P0, and the first program state P1) of the string selection transistors SST1a to SST2c.

When the string selection transistors are programmed based on the second SST coding pattern SCP2, the 1c-th and 2c-th string selection transistors SST1c and SST2c may have the 0-th program state P0, the 2a-th and 1b-th string selection transistors SST2a and SST1b may have the first program state P1, and the remaining string selection transistors SST1a and SST2b may have the 0-th erase state E0.

When the string selection transistors SST1a to SST2c are programmed as illustrated in FIG. 9, it may be possible to individually control cell strings based on string selection lines, the number of which is less than the number of cell strings.

For example, as illustrated in FIG. 10A, it is assumed that the a-th cell string CSa is a selected cell string. In this case, according to the second SST coding pattern SCP2, because the 1a-th string selection transistor SST1a of the a-th cell string CSa is in the 0-th erase state E0 and the remaining string selection transistor SST2a is in the first program state P1, the first on-voltage VON1 may be applied to the first string selection line SSL1, and the third on-voltage VON3 may be applied to the second string selection line SSL2.

According to the bias condition of the string selection lines SSL1 and SSL2 of FIG. 10A, the string selection transistors SST1a and SST2a of the a-th cell string CSa may be turned on. The 1b-th string selection transistor SST1b of the b-th cell string CSb and the 1c-th string selection transistor SST1c of the c-th cell string CSc may be turned off by the first on-voltage VON1 of the first string selection line SSL1.

As illustrated in FIG. 10A, when the a-th cell string CSa is the selected cell string, in each of the b-th and c-th cell strings CSb and CSc being unselected cell strings, at least one string selection transistor may be turned off. Accordingly, the a-th cell string CSa may be individually controlled. When the b-th cell string CSb is a selected cell string, the b-th cell string CSb may operate to be similar to that when the a-th cell string CSa is a selected cell string.

Next, as illustrated in FIG. 10B, it is assumed that the c-th cell string CSc is a selected cell string. In this case, according to the second SST coding pattern SCP2, because the 1c-th and 2c-th string selection transistors SST1c and SST2c of the c-th cell string CSc are in the 0-th program state P0, the second on-voltage VON2 may be applied to the first and second string selection lines SSL1 and SSL2.

According to the bias condition of the string selection lines SSL1 and SSL2 of FIG. 10B, the string selection transistors SST1c and SST2c of the c-th cell string CSc may be turned on. The 1b-th string selection transistor SST1b of the b-th cell string CSb may be turned off by the second on-voltage VON2 of the first string selection line SSL1. The 2a-th string selection transistor SST2a of the a-th cell string CSa may be turned off by the second on-voltage VON2 of the second string selection line SSL2.

As illustrated in FIG. 10B, when the c-th cell string CSc is a selected cell string, in each of the a-th and b-th cell strings CSa and CSb being unselected cell strings, at least one string selection transistor may be turned off. Accordingly, the c-th cell string CSc may be individually controlled.

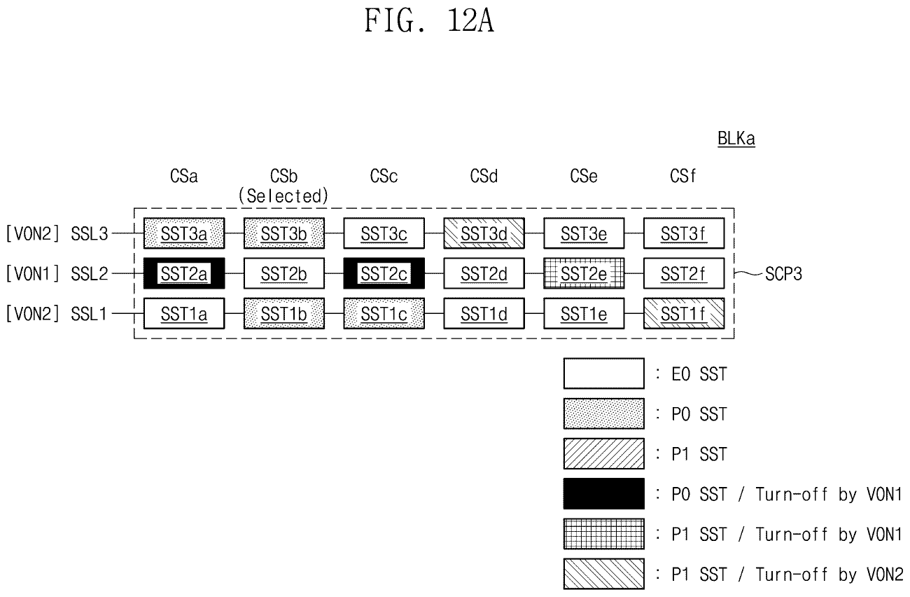

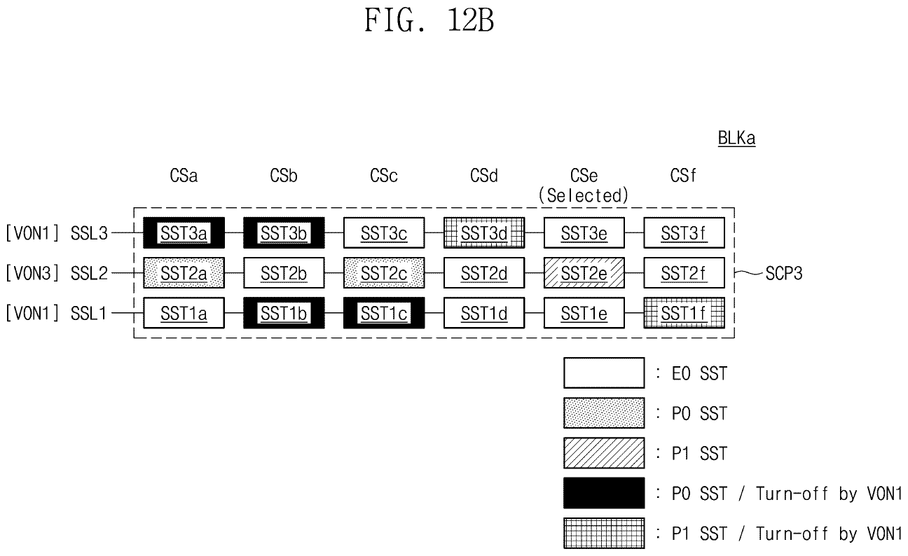

FIG. 11 is a diagram illustrating a string selection transistor coding pattern of string selection transistors of a memory block according to an embodiment of the present disclosure. FIGS. 12A and 12B are diagrams for describing an operation of a memory block including string selection transistors programmed depending on the string selection transistor coding pattern of FIG. 11.

First, referring to FIGS. 1, 8, 11, 12A, and 12B, the memory block BLKa may include the first to third string selection lines SSL1 to SSL3 and the a-th to f-th cell strings CSa to CSf. The a-th cell string CSa may include a plurality of string selection transistors SST1a to SST3a, the b-th cell string CSb may include a plurality of string selection transistors SST1b to SST3b, the c-th cell string CSc may include a plurality of string selection transistors SST1c to SST3c, the d-th cell string CSd may include a plurality of string selection transistors SST1d to SST3d, the e-th cell string CSe may include a plurality of string selection transistors SST1e to SST3e, and the f-th cell string CSf may include a plurality of string selection transistors SST1f to SST3f.

In an embodiment, as described above, each of the a-th to f-th cell strings CSa to CSf may further include at least one ground selection transistor GST, a plurality of memory cells MC, and at least one dummy memory cell dMC.

The string selection transistors SST1a, SST1b, SST1c, SST1d, SST1e, and SST1f of the a-th to f-th cell strings CSa to CSf may be connected to the first string selection line SSL1; the string selection transistors SST2a, SST2b, SST2c, SST2d, SST2e, and SST2f of the a-th to f-th cell strings CSa to CSf may be connected to the second string selection line SSL2; and, the string selection transistors SST3a, SST3b, SST3c, SST3d, SST3e, and SST3f of the a-th to f-th cell strings CSa to CSf may be connected to the third string selection line SSL3.

The string selection transistors SST1a to SST3f connected to the first to third string selection lines SSL1 to SSL3 may be programmed based on a third SST coding pattern SCP3. For example, the third SST coding pattern SCP3 may refer to information indicating threshold voltage states (e.g., the 0-th erase state E0, the 0-th program state P0, and the first program state P1) of the string selection transistors SST1a to SST3f.

When the string selection transistors SST1a to SST3f are programmed based on the third SST coding pattern SCP3, the 2a-th, 3a-th, 1b-th, 3b-th, 1c-th, and 2c-th string selection transistors SST2a, SST3a, SST1b, SST3b, SST1c, and SST2c may have the 0-th program state P0, the 3d-th, 2e-th, and 1f-th string selection transistors SST3d, SST2e, and SST1f may have the first program state P1, and the remaining string selection transistors SST1a, SST2b, SST3c, SST1d, SST2d, SST1e, SST3e, SST2f, and SST3f may have the 0-th erase state E0.

When the string selection transistors SST1a to SST3f are programmed as illustrated in FIG. 11, it may be possible to individually control cell strings based on string selection lines, the number of which is less than the number of cell strings.

For example, as illustrated in FIG. 12A, it is assumed that the b-th cell string CSb is a selected cell string. In this case, according to the third SST coding pattern SCP3, because the 2b-th string selection transistor SST2b of the b-th cell string CSb is in the 0-th erase state E0 and the remaining string selection transistor SST1b and SST3b is in the 0-th program state P0, the first on-voltage VON1 may be applied to the second string selection line SSL2, and the second on-voltage VON2 may be applied to the remaining string selection lines SSL1 and SSL3.

According to the bias condition of the string selection lines SSL1 to SSL3 of FIG. 12A, the string selection transistors SST1b to SST3b of the b-th cell string CSb may be turned on. The 1f-th string selection transistor SST1f of the f-th cell string CSf may be turned off by the second on-voltage VON2 of the first string selection line SSL1. The 2a-th string selection transistor SST2a of the a-th cell string CSa, the 2c-th string selection transistor SST2c of the c-th cell string CSc, and the 2e-th string selection transistor SST2e of the e-th cell string CSe may be turned off by the first on-voltage VON1 of the second string selection line SSL2. The 3d-th string selection transistor SST3d of the d-th cell string CSd may be turned off by the second on-voltage VON2 of the third string selection line SSL3.

As illustrated in FIG. 12A, when the b-th cell string CSb is a selected cell string, in each of the a-th, c-th, d-th, e-th, and f-th cell strings CSa, CSc, CSd, CSe, and CSf being unselected cell strings, at least one string selection transistor may be turned off. Accordingly, the b-th cell string CSb may be individually controlled. When the a-th cell string CSa or the c-th cell string CSc is a selected cell string, the a-th cell string CSa or the c-th cell string CSc may operate to be similar to that when the b-th cell string CSb is a selected cell string.

Then, as illustrated in FIG. 12B, it is assumed that the e-th cell string CSe is a selected cell string. In this case, according to the third SST coding pattern SCP3, because the 1e-th and 3e-th string selection transistors SST1e and SST3e of the e-th cell string CSe are in the 0-th erase state E0 and the remaining string selection transistor SST2e is in the first program state P1, the first on-voltage VON1 may be applied to the first and third string selection lines SSL1 and SSL3, and the third on-voltage VON3 may be applied to the second string selection line SSL2.

According to the bias condition of the string selection lines SSL1 to SSL3 of FIG. 12B, the string selection transistors SST1e to SST3e of the e-th cell string CSe may be turned on. The 1b-th string selection transistor SST1b of the b-th cell string CSb, the 1c-th string selection transistor SST1c of the c-th cell string CSc, and the 1f-th string selection transistor SST1f of the f-th cell string CSf may be turned off by the first on-voltage VON1 of the first string selection line SSL1. The 3a-th string selection transistor SST3a of the a-th cell string CSa, the 3b-th string selection transistor SST3b of the b-th cell string CSb, and the 3d-th string selection transistor SST3d of the d-th cell string CSd may be turned off by the first on-voltage VON1 of the third string selection line SSL3.

As illustrated in FIG. 12B, when the e-th cell string CSe is a selected cell string, in each of the a-th, b-th, c-th, d-th, and f-th cell strings CSa, CSb, CSc, CSd, and CSf being unselected cell strings, at least one string selection transistor may be turned off. Accordingly, the e-th cell string CSe may be individually controlled. When the d-th cell string CSd or the f-th cell string CSf is a selected cell string, the d-th cell string CSd or the f-th cell string CSf may operate to be similar to that when the e-th cell string CSe is a selected cell string.

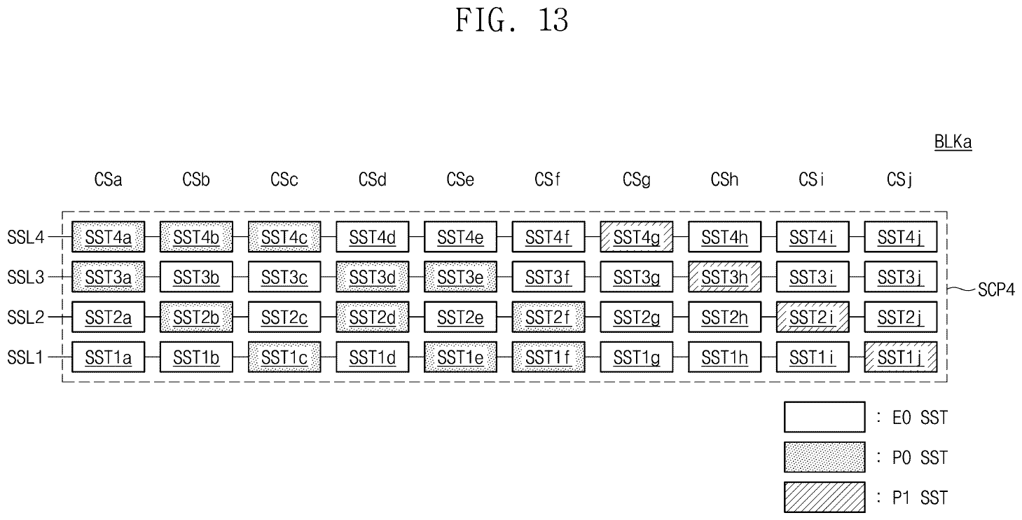

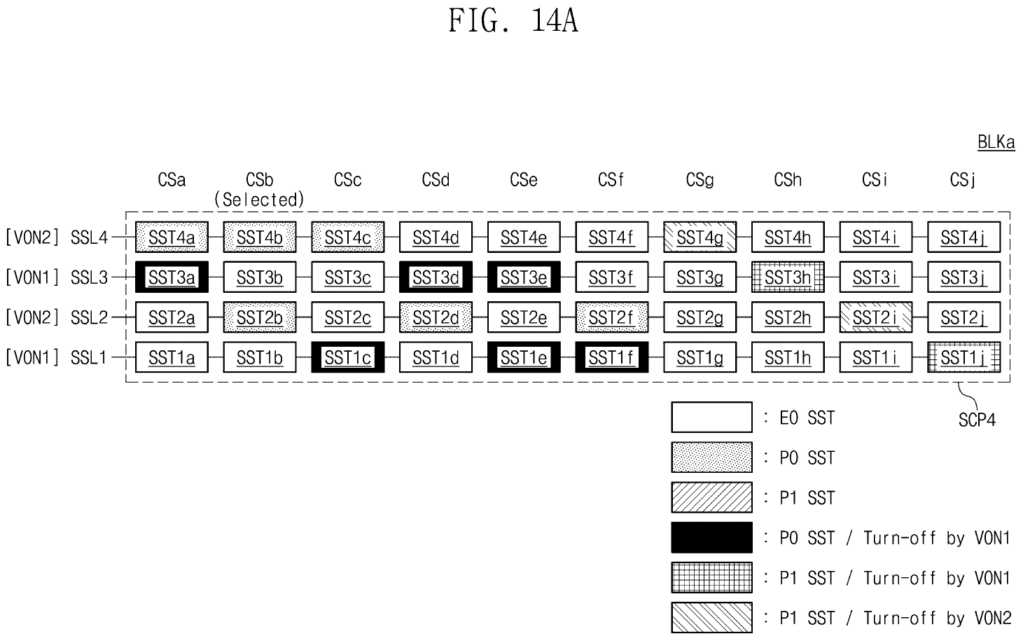

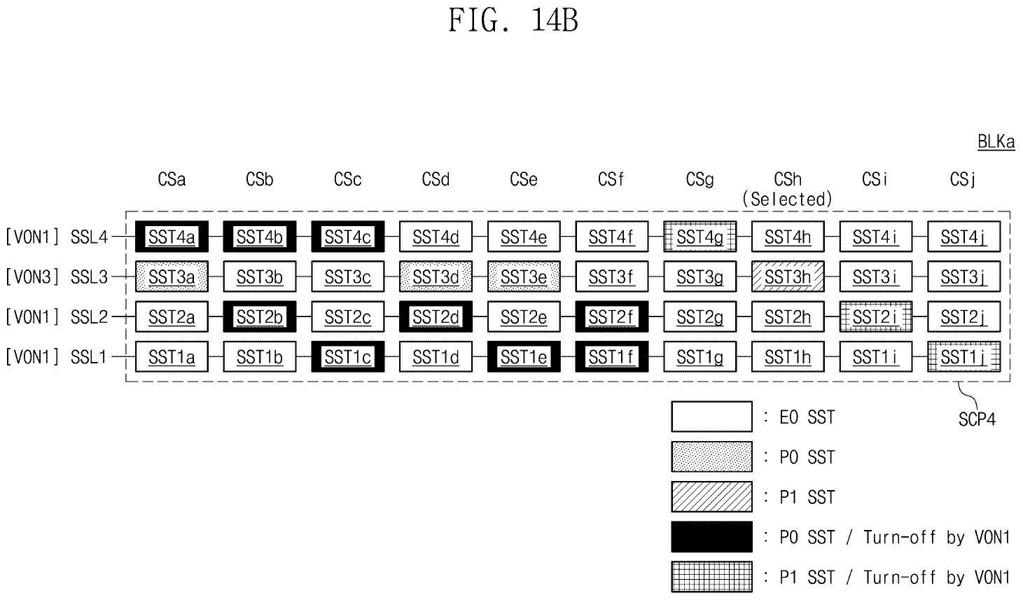

FIG. 13 is a diagram illustrating a string selection transistor coding pattern of string selection transistors of a memory block according to an embodiment of the present disclosure. FIGS. 14A and 14B are diagrams for describing an operation of a memory block including string selection transistors programmed depending on the string selection transistor coding pattern of FIG. 13.

First, referring to FIGS. 1, 8, 13, 14A, and 14B, the memory block BLKa may include the first to fourth string selection lines SSL1 to SSL4 and a-th to j-th cell strings CSa to CSj. The a-th cell string CSa may include a plurality of string selection transistors SST1a to SST4a; the b-th cell string CSb may include a plurality of string selection transistors SST1b to SST4b; the c-th cell string CSc may include a plurality of string selection transistors SST1c to SST4c; the d-th cell string CSd may include a plurality of string selection transistors SST1d to SST4d; the e-th cell string CSe may include a plurality of string selection transistors SST1e to SST4e; the f-th cell string CSf may include a plurality of string selection transistors SST1f to SST4f; the g-th cell string CSg may include a plurality of string selection transistors SST1g to SST4g; the h-th cell string CSh may include a plurality of string selection transistors SST1h to SST4h; the i-th cell string CSi may include a plurality of string selection transistors SST1i to SST4i; and, the j-th cell string CSj may include a plurality of string selection transistors SST1j to SST4j.

In an embodiment, as described above, each of the a-th to j-th cell strings CSa to CSj may further include at least one ground selection transistor GST, a plurality of memory cells MC, and at least one dummy memory cell dMC.

The string selection transistors SST1a, SST1b, SST1c, SST1d, SST1e, SST1f, SST1g, SST1h, SST1i, and SST1j of the a-th to j-th cell strings CSa to CSj may be connected to the first string selection line SSL1; the string selection transistors SST2a, SST2b, SST2c, SST2d, SST2e, SST2f, SST2g, SST2h, SST2i, and SST2j of the a-th to j-th cell strings CSa to CSj may be connected to the second string selection line SSL2; the string selection transistors SST3a, SST3b, SST3c, SST3d, SST3e, SST3f, SST3g, SST3h, SST3i, and SST3j of the a-th to j-th cell strings CSa to CSj may be connected to the third string selection line SSL3; and, the string selection transistors SST4a, SST4b, SST4c, SST4d, SST4e, SST4f, SST4g, SST4h, SST4i, and SST4j of the a-th to j-th cell strings CSa to CSj may be connected to the fourth string selection line GSLA.

The string selection transistors SST1a to SST4j connected to the first to fourth string selection lines SSL1 to SSL4 may be programmed based on a fourth SST coding pattern SCP4. For example, the fourth SST coding pattern SCP4 may refer to information indicating threshold voltage states (e.g., the 0-th erase state E0, the 0-th program state P0, and the first program state P1) of the string selection transistors SST1a to SST4j.

When the string selection transistors SST1a to SST4j are programmed based on the fourth SST coding pattern SCP4, the 3a-th, 4a-th, 2b-th, 4b-th, 1c-th, 4c-th, 2d-th, 3d-th, 1e-Th, 3e-Th, 1f-Th, and 2f-Th String Selection Transistors SST3a, SST4a, SST2b, SST4b, SST1c, SST4c, SST2d, SST3d, SST1e, SST3e, SST1f, and SST2f may have the 0-th program state P0, the 4g-th, 3h-th, 2i-th, and 1j-th string selection transistors SST4g, SST3h, SST2i, and SST1j may have the first program state P1, and the remaining string selection transistors SST1a, SST2a, SST1b, SST3b, SST2c, SST3c, SST1d, SST4d, SST2e, SST4e, SST3f, SST4f, SST1g, SST2g, SST3g, SST1h, SST2h, SST4h, SST1i, SST3i, SST4i, SST2j, SST3j, and SST4j may have the 0-th erase state E0.

When the string selection transistors SST1a to SST4j are programmed as illustrated in FIG. 13, it may be possible to individually control cell strings based on string selection lines, the number of which is less than the number of cell strings.

For example, as illustrated in FIG. 14A, it is assumed that the b-th cell string CSb is a selected cell string. In this case, according to the fourth SST coding pattern SCP4, because the 1b-th and 3b-th string selection transistors SST1b and SST3b of the b-th cell string CSb are in the 0-th erase state E0 and the remaining string selection transistors SST2b and SST4b are in the 0-th program state P0, the first on-voltage VON1 may be applied to the first and third string selection lines SSL1 and SSL3, and the second on-voltage VON2 may be applied to the remaining string selection lines SSL2 and SSLA.

According to the bias condition of the string selection lines SSL1 to SSLA of FIG. 14A, the string selection transistors SST1b to SST4b of the b-th cell string CSb may be turned on. The 1c-th string selection transistor SST1c of the c-th cell string CSc, the 1e-th string selection transistor SST1e of the e-th cell string CSe, the 1f-th string selection transistor SST1f of the f-th cell string CSf, and the 1j-th string selection transistor SST1j of the j-th cell string CSj may be turned off by the first on-voltage VON1 of the first string selection line SSL1. The 2i-th string selection transistor SST2i of the i-th cell string CSi may be turned off by the second on-voltage VON2 of the second string selection line SSL2. The 3a-th string selection transistor SST3a of the a-th cell string CSa, the 3d-th string selection transistor SST3d of the d-th cell string CSd, the 3e-th string selection transistor SST3e of the e-th cell string CSe, and the 3h-th string selection transistor SST3h of the h-th cell string CSh may be turned off by the first on-voltage VON1 of the third string selection line SSL3. The 4g-th string selection transistor SST4g of the g-th cell string CSg may be turned off by the second on-voltage VON2 of the fourth string selection line SSLA.

As illustrated in FIG. 14A, when the b-th cell string CSb is a selected cell string, in each of the a-th, c-th, d-th, e-th, f-th, g-th, h-th, i-th, and j-th cell strings CSa, CSc, CSd, CSe, CSf, CSg, CSh, CSi, and CSj being unselected cell strings, at least one string selection transistor may be turned off. Accordingly, the b-th cell string CSb may be individually controlled. When the a-th, c-th, d-th, e-th, or f-th cell string CSa, CSc, CSd, CSe, or CSf is a selected cell string, the a-th, c-th, d-th, e-th, or f-th cell string CSa, CSc, CSd, CSe, or CSf may operate to be similar to that when the b-th cell string CSb is a selected cell string.

As illustrated in FIG. 14B, it is assumed that the h-th cell string CSh is a selected cell string. In this case, according to the fourth SST coding pattern SCP4, because the 1h-th, 2h-th, and 4h-th string selection transistors SST1h, SST2h, and SST4h of the h-th cell string CSh are in the 0-th erase state E0 and the remaining string selection transistor SST3h is in the first program state P1, the first on-voltage VON1 may be applied to the first, second, and fourth string selection lines SSL1, SSL2, and SSL4, and the third on-voltage VON3 may be applied to the third string selection line SSL3.

According to the bias condition of the string selection lines SSL1 to SSLA of FIG. 14B, the string selection transistors SST1h to SST4h of the h-th cell string CSh may be turned on. The 1c-th string selection transistor SST1c of the c-th cell string CSc, the 1e-th string selection transistor SST1e of the e-th cell string CSe, the 1f-th string selection transistor SST1f of the f-th cell string CSf, and the 1j-th string selection transistor SST1j of the j-th cell string CSj may be turned off by the first on-voltage VON1 of the first string selection line SSL1. The 2b-th string selection transistor SST2b of the b-th cell string CSb, the 2d-th string selection transistor SST2d of the d-th cell string CSd, the 2f-th string selection transistor SST2f of the f-th cell string CSf, and the 2i-th string selection transistor SST2i of the i-th cell string CSi may be turned off by the first on-voltage VON1 of the second string selection line SSL2. The 4a-th string selection transistor SST4a of the a-th cell string CSa, the 4b-th string selection transistor SST4b of the b-th cell string CSb, the 4c-th string selection transistor SST4c of the c-th cell string CSc, and the 4g-th string selection transistor SST4g of the g-th cell string CSg may be turned off by the first on-voltage VON1 of the fourth string selection line SSL4.

As illustrated in FIG. 14B, when the h-th cell string CSh is a selected cell string, in each of the a-th, b-th, c-th, d-th, e-th, f-th, g-th, i-th, and j-th cell strings CSa, CSb, CSc, CSd, CSe, CSf, CSg, CSi, and CSj being unselected cell strings, at least one string selection transistor may be turned off. Accordingly, the h-th cell string CSh may be individually controlled. When the g-th, i-th, or j-th cell string CSg, CSi, or CSj is a selected cell string, the g-th, i-th, or j-th cell string CSg, CSi, or CSj may operate to be similar to that when the h-th cell string CSh is a selected cell string.

In FIGS. 9 to 14B, the operation of individually controlling the three cell strings CSa to CSc based on the two string selection lines SSL1 and SSL2, the operation of individually controlling the six cell strings CSa to CSf based on the three string selection lines SSL1 to SSL3, the operation of individually controlling the ten cell strings CSa to CSj based on the four string selection lines SSL1 to SSLA are described based on the memory block BLKa based on a string selection transistor (i.e., 3-stage SST) having the 0-th erase state E0, the 0-th program state P0, or the first program state P1, but the present disclosure is not limited thereto. For example, in the memory block BLKa based on the 3-stage SST, the number of cell strings which are capable of being individually controlled based on the four string selection lines SSL1 to SSL4 may be calculated based on Equation 2 below.

$$n = a + b \qquad [ Equation 2 ]$$

$$a = C ( m , [ ( m - 1 ) / 2 ] )$$

$$b = C ( m , [ ( m + 1 ) / 2 ] )$$

In Equation 2 above, in the memory block BLKa based on the 3-stage SST, “m” indicates the number of string selection lines, and “n” indicates the number of cell strings capable of being individually controlled based on the “m” string selection lines. Herein, for integers x and y greater than or equal to 0, C (x, y) is a function indicating the number of cases of combining y out of x, and [x] is a function indicating the largest integer not greater than x.

Referring to Equation 2, “p” cell strings may respectively correspond to different combinations in which [(m−1)/2] string selection transistors among the “m” string selection transistors have the 0-th erase state E0 and the remaining string selection transistors have the 0-th program state P0. Also, “q” cell strings may respectively correspond to different combinations in which [(m+1)/2] string selection transistors among the “m” string selection transistors have the 0-th erase state E0 and the remaining string selection transistors have the first program state P1. Accordingly, in FIGS. 9 to 10B, because the number of string selection lines is two (i.e., m=2), p=1, q=2, and the number of cell strings capable of being individually controlled may be three (i.e., n=p+q=3). Also, in FIGS. 11 to 12B, because the number of string selection lines is three (i.e., m=3), p=3, q=3, and the number of cell strings capable of being individually controlled may be six (i.e., n=p+q=6).

In particular, when “m” is an even number of 4 or more, the “q” cell strings may respectively correspond to different combinations in which [(m+1)/2] string selection transistors among the “m” string selection transistors have the 0-th erase state E0 and the remaining string selection transistors have the 0-th program state P0. Also, “p” cell strings may respectively correspond to different combinations in which ([(m+1)/2]+1) string selection transistors have the 0-th erase state E0 and the remaining string selection transistors have the first program state P1. Accordingly, in FIGS. 13 to 14B, because the number of string selection lines is four (i.e., m=4), p=6, q=4, and the number of cell strings capable of being individually controlled may be ten (i.e., n=p+q=10). That is, the SST coding pattern for individually controlling an identical number of cell strings based on an identical number of string selection lines may be variously implemented.

In the present disclosure, the description is given as the memory block BLKa of FIGS. 5A to 7F is based on the 2-stage SST and the memory block BLKa of FIGS. 9 to 14B is based on the 3-stage SST. However, this is provided as an example, and the present disclosure is not limited thereto. For example, the memory block BLKa may be based on a string selection transistor capable of having one of a plurality of (e.g., four or more) threshold voltage states. In this case, more cell strings may be individually controlled based on an identical number of string selection lines. In detail, as the number of threshold voltage states which a string selection transistor is capable of having increases, the number of cell strings capable of being individually controlled may increase.

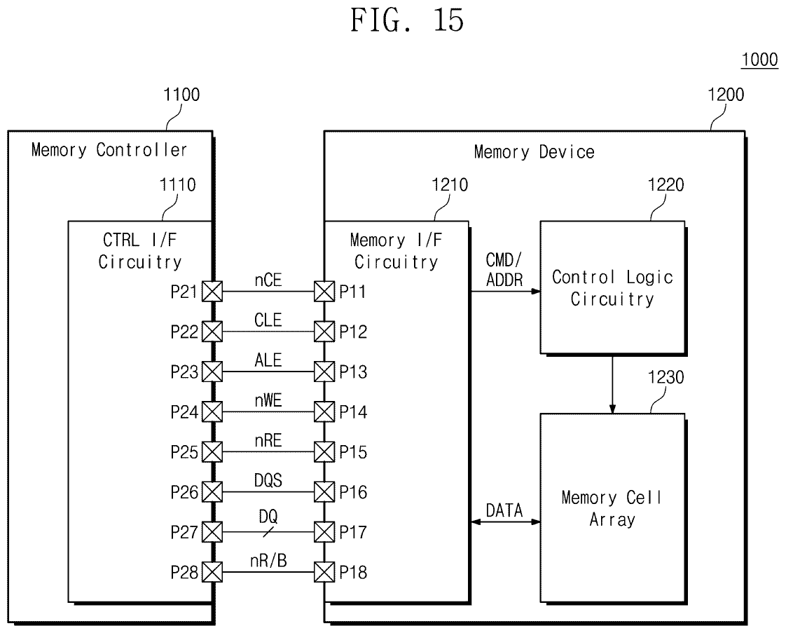

FIG. 15 is a block diagram illustrating a memory system according to an embodiment of the present disclosure. Referring to FIG. 15, the memory system 1000 may include a memory device 1200 and a memory controller 1100.

The memory device 1200 may include first to eighth pins P11 to P18, a memory interface circuitry 1210, a control logic circuitry 1220, and a memory cell array 1230.

The memory interface circuitry 1210 may receive a chip enable signal nCE from the memory controller 1100 through the first pin P11. The memory interface circuitry 1210 may transmit and receive signals to and from the memory controller 1100 through the second to eighth pins P12 to P18 in response to the chip enable signal nCE. For example, when the chip enable signal nCE is in an enable state (e.g., a low level), the memory interface circuitry 1210 may transmit and receive signals to and from the memory controller 1100 through the second to eighth pins P12 to P18.

The memory interface circuitry 1210 may receive a command latch enable signal CLE, an address latch enable signal ALE, and a write enable signal nWE from the memory controller 1100 through the second to fourth pins P12 to P14. The memory interface circuitry 1210 may receive a data signal DQ from the memory controller 1100 through the seventh pin P17 or transmit the data signal DQ to the memory controller 1100. A command CMD, an address ADDR, and data may be transmitted via the data signal DQ. For example, the data signal DQ may be transmitted through a plurality of data signal lines. In this case, the seventh pin P17 may include a plurality of pins respectively corresponding to a plurality of data signals DQ(s).

The memory interface circuitry 1210 may obtain the command CMD from the data signal DQ, which is received in an enable section (e.g., a high-level state) of the command latch enable signal CLE based on toggle time points of the write enable signal nWE. The memory interface circuitry 1210 may obtain the address ADDR from the data signal DQ, which is received in an enable section (e.g., a high-level state) of the address latch enable signal ALE based on the toggle time points of the write enable signal nWE.

In an example embodiment, the write enable signal nWE may be maintained at a static state (e.g., a high level or a low level) and toggle between the high level and the low level. For example, the write enable signal nWE may toggle in a section in which the command CMD or the address ADDR is transmitted. Thus, the memory interface circuitry 1210 may obtain the command CMD or the address ADDR based on toggle time points of the write enable signal nWE.

The memory interface circuitry 1210 may receive a read enable signal nRE from the memory controller 1100 through the fifth pin P15. The memory interface circuitry 1210 may receive a data strobe signal DQS from the memory controller 1100 through the sixth pin P16 or transmit the data strobe signal DQS to the memory controller 1100.

In a data (DATA) output operation of the memory device 1200, the memory interface circuitry 1210 may receive the read enable signal nRE, which toggles through the fifth pin P15, before outputting the data DATA. The memory interface circuitry 1210 may generate the data strobe signal DQS, which toggles based on the toggling of the read enable signal nRE. For example, the memory interface circuitry 1210 may generate a data strobe signal DQS, which starts toggling after a predetermined delay (e.g., tDQSRE), based on a toggling start time of the read enable signal nRE. The memory interface circuitry 1210 may transmit the data signal DQ including the data DATA based on a toggle time point of the data strobe signal DQS. Thus, the data DATA may be aligned with the toggle time point of the data strobe signal DQS and transmitted to the memory controller 1100.

In a data (DATA) input operation of the memory device 1200, when the data signal DQ including the data DATA is received from the memory controller 1100, the memory interface circuitry 1210 may receive the data strobe signal DQS, which toggles, along with the data DATA from the memory controller 1100. The memory interface circuitry 1210 may obtain the data DATA from the data signal DQ based on toggle time points of the data strobe signal DQS. For example, the memory interface circuitry 1210 may sample the data signal DQ at rising and falling edges of the data strobe signal DQS and obtain the data DATA.

The memory interface circuitry 1210 may transmit a ready/busy output signal nR/B to the memory controller 1100 through the eighth pin P18. The memory interface circuitry 1210 may transmit state information of the memory device 1200 through the ready/busy output signal nR/B to the memory controller 1100. When the memory device 1200 is in a busy state (i.e., when operations are being performed in the memory device 1200), the memory interface circuitry 1210 may transmit a ready/busy output signal nR/B indicating the busy state to the memory controller 1100. When the memory device 1200 is in a ready state (i.e., when operations are not performed or completed in the memory device 1200), the memory interface circuitry 1210 may transmit a ready/busy output signal nR/B indicating the ready state to the memory controller 1100. For example, while the memory device 1200 is reading data DATA from the memory cell array 1230 in response to a page read command, the memory interface circuitry 1210 may transmit a ready/busy output signal nR/B indicating a busy state (e.g., a low level) to the memory controller 1100. For example, while the memory device 1200 is programming data DATA to the memory cell array 1230 in response to a program command, the memory interface circuitry 1210 may transmit a ready/busy output signal nR/B indicating the busy state to the memory controller 1100.

The control logic circuitry 1220 may control all operations of the memory device 1200. The control logic circuitry 1220 may receive the command/address CMD/ADDR obtained from the memory interface circuitry 1210. The control logic circuitry 1220 may generate control signals for controlling other components of the memory device 1200 in response to the received command/address CMD/ADDR. For example, the control logic circuitry 1220 may generate various control signals for programming data DATA to the memory cell array 1230 or reading the data DATA from the memory cell array 1230.

The memory cell array 1230 may store the data DATA obtained from the memory interface circuitry 1210, via the control of the control logic circuitry 1220. The memory cell array 1230 may output the stored data DATA to the memory interface circuitry 1210 via the control of the control logic circuitry 1220.

The memory cell array 1230 may include a plurality of memory cells. For example, the plurality of memory cells may be flash memory cells. However, embodiments are not limited thereto, and the memory cells may be RRAM cells, FRAM cells, PRAM cells, thyristor RAM (TRAM) cells, or MRAM cells. Hereinafter, an embodiment in which the memory cells are NAND flash memory cells will mainly be described.

The memory controller 1100 may include first to eighth pins P21 to P28 and a controller interface circuitry 1110. The first to eighth pins P21 to P28 may respectively correspond to the first to eighth pins P11 to P18 of the memory device 1200.

The controller interface circuitry 1110 may transmit a chip enable signal nCE to the memory device 1200 through the first pin P21. The controller interface circuitry 1110 may transmit and receive signals to and from the memory device 1200, which is selected by the chip enable signal nCE, through the second to eighth pins P22 to P28.

The controller interface circuitry 1110 may transmit the command latch enable signal CLE, the address latch enable signal ALE, and the write enable signal nWE to the memory device 1200 through the second to fourth pins P22 to P24. The controller interface circuitry 1110 may transmit or receive the data signal DQ to and from the memory device 1200 through the seventh pin P27.

The controller interface circuitry 1110 may transmit the data signal DQ including the command CMD or the address ADDR to the memory device 1200 along with the write enable signal nWE, which toggles. The controller interface circuitry 1110 may transmit the data signal DQ including the command CMD to the memory device 1200 by transmitting a command latch enable signal CLE having an enable state. Also, the controller interface circuitry 1110 may transmit the data signal DQ including the address ADDR to the memory device 1200 by transmitting an address latch enable signal ALE having an enable state.

The controller interface circuitry 1110 may transmit the read enable signal nRE to the memory device 1200 through the fifth pin P25. The controller interface circuitry 1110 may receive or transmit the data strobe signal DQS from or to the memory device 1200 through the sixth pin P26.

In a data (DATA) output operation of the memory device 1200, the controller interface circuitry 1110 may generate a read enable signal nRE, which toggles, and transmit the read enable signal nRE to the memory device 1200. For example, before outputting data DATA, the controller interface circuitry 1110 may generate a read enable signal nRE, which is changed from a static state (e.g., a high level or a low level) to a toggling state. Thus, the memory device 1200 may generate a data strobe signal DQS, which toggles, based on the read enable signal nRE. The controller interface circuitry 1110 may receive the data signal DQ including the data DATA along with the data strobe signal DQS, which toggles, from the memory device 1200. The controller interface circuitry 1110 may obtain the data DATA from the data signal DQ based on a toggle time point of the data strobe signal DQS.

In a data (DATA) input operation of the memory device 1200, the controller interface circuitry 1110 may generate a data strobe signal DQS, which toggles. For example, before transmitting data DATA, the controller interface circuitry 1110 may generate a data strobe signal DQS, which is changed from a static state (e.g., a high level or a low level) to a toggling state. The controller interface circuitry 1110 may transmit the data signal DQ including the data DATA to the memory device 1200 based on toggle time points of the data strobe signal DQS.

The controller interface circuitry 1110 may receive a ready/busy output signal nR/B from the memory device 1200 through the eighth pin P28. The controller interface circuitry 1110 may determine state information of the memory device 1200 based on the ready/busy output signal nR/B.

In an embodiment, the memory device 1200 may be the nonvolatile memory device 100 described with reference to FIGS. 1 to 14B. The memory cell array 1230 of the memory device 1200 may include a plurality of memory blocks, and each of the plurality of memory blocks may include a plurality of string selection transistors. The plurality of string selection transistors may be programmed based on the SST coding pattern described with reference to FIGS. 1 to 14B.

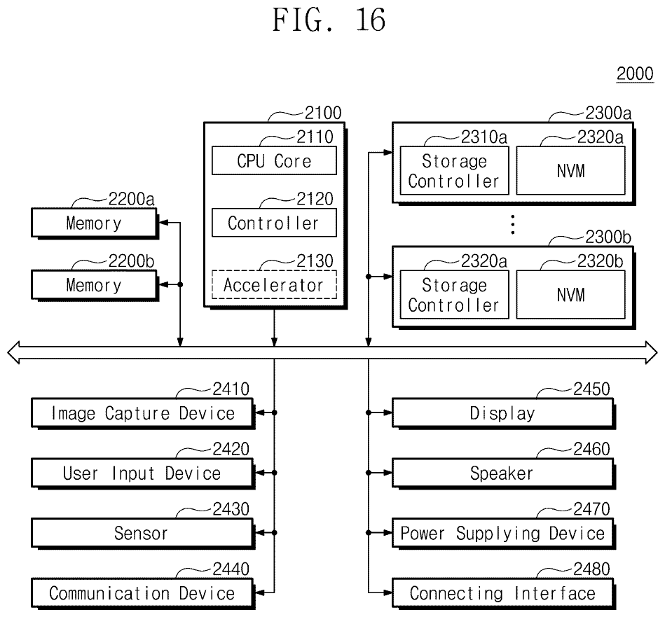

FIG. 16 is a diagram illustrating a system to which a storage device according to an embodiment of the present disclosure is applied. The system 2000 of FIG. 16 may basically be a mobile system, such as a portable communication terminal (e.g., a mobile phone), a smartphone, a tablet personal computer (PC), a wearable device, a healthcare device, or an Internet of things (IOT) device. However, the system 2000 of FIG. 16 is not necessarily limited to the mobile system and may be a PC, a laptop computer, a server, a media player, or an automotive device (e.g., a navigation device).

Referring to FIG. 16, the system 2000 may include a main processor 200, memories (e.g., 2200a and 2200b), and storage devices (e.g., 2300a and 2300b). In addition, the system 2000 may include at least one of an image capturing device 2410, a user input device 2420, a sensor 2430, a communication device 2440, a display 2450, a speaker 2460, a power supplying device 2470, and a connecting interface 2480.

The main processor 2100 may control all operations of the system 2000, more specifically, operations of other components included in the system 2000. The main processor 2100 may be implemented as a general-purpose processor, a dedicated processor, or an application processor.

The main processor 2100 may include at least one CPU core 2110 and further include a controller 2120 configured to control the memories 2200a and 2200b and/or the storage devices 2300a and 2300b. In some embodiments, the main processor 2100 may further include an accelerator 2130, which is a dedicated circuit for a high-speed data operation, such as an artificial intelligence (AI) data operation. The accelerator 2130 may include a graphics processing unit (GPU), a neural processing unit (NPU) and/or a data processing unit (DPU) and be implemented as a chip that is physically separate from the other components of the main processor 2100.

The memories 2200a and 2200b may be used as main memory devices of the memory system 1000. Although each of the memories 2200a and 2200b may include a volatile memory, such as static random access memory (SRAM) and/or dynamic RAM (DRAM), each of the memories 2200a and 2200b may include non-volatile memory, such as a flash memory, phase-change RAM (PRAM) and/or resistive RAM (RRAM). The memories 2200a and 2200b may be implemented in the same package as the main processor 2100.

The storage devices 2300a and 2300b may serve as non-volatile storage devices configured to store data regardless of whether power is supplied thereto, and have larger storage capacity than the memories 2200a and 2200b. The storage devices 2300a and 2300b may respectively include storage controllers (STRG CTRL) 2310a and 2310b and NVM (Non-Volatile Memory) s 2320a and 2320b configured to store data via the control of the storage controllers 2310a and 2310b. Although the NVMs 2320a and 2320b may include flash memories having a two-dimensional (2D) structure or a three-dimensional (3D) V-NAND structure, the NVMs 2320a and 2320b may include other types of NVMs, such as PRAM and/or RRAM.

The storage devices 2300a and 2300b may be physically separated from the main processor 2100 and included in the system 2000 or implemented in the same package as the main processor 2100. In addition, the storage devices 2300a and 2300b may have types of solid-state devices (SSDs) or memory cards and be removably combined with other components of the system 2000 through an interface, such as the connecting interface 2480 that will be described below. The storage devices 2300a and 2300b may be devices to which a standard protocol, such as a universal flash storage (UFS), an embedded multi-media card (eMMC), or a non-volatile memory express (NVMe), is applied, without being limited thereto.

The image capturing device 2410 may capture still images or moving images. The image capturing device 2410 may include a camera, a camcorder, and/or a webcam.

The user input device 2420 may receive various types of data input by a user of the system 2000 and include a touch pad, a keypad, a keyboard, a mouse, and/or a microphone.

The sensor 2430 may detect various types of physical quantities, which may be obtained from the outside of the system 2000, and convert the detected physical quantities into electric signals. The sensor 2430 may include a temperature sensor, a pressure sensor, an illuminance sensor, a position sensor, an acceleration sensor, a biosensor, and/or a gyroscope sensor.

The communication device 2440 may transmit and receive signals between other devices outside the system 2000 according to various communication protocols. The communication device 2440 may include an antenna, a transceiver, and/or a modem.

The display 2450 and the speaker 2460 may serve as output devices configured to respectively output visual information and auditory information to the user of the system 2000.

The power supplying device 2470 may appropriately convert power supplied from a battery embedded in the system 2000 and/or an external power source, and supply the converted power to each of components of the system 2000.

The connecting interface 2480 may provide connection between the system 2000 and an external device, which is connected to the system 2000 and capable of transmitting and receiving data to and from the system 2000. The connecting interface 2480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In an embodiment, the nonvolatile memories 2320a and 2320b of the storage devices 2300a and 2300b of FIG. 16 may be implemented with the nonvolatile memory device 100 described with reference to FIGS. 1 to 14B.

According to the present disclosure, a nonvolatile memory device may individually control more cell strings by using less string selection lines. Accordingly, a nonvolatile memory device including a plurality of string selection transistors with improved performance and high manufacturing cost efficiency is provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A nonvolatile memory device comprising:
a first cell string to an n-th cell string connected in parallel between a bit line and a common source line,
wherein each of the first to n-th cell strings comprises:
a corresponding one of a first ground selection transistor to an n-th ground selection transistor respectively connected to a first ground selection line to an n-th ground selection line; and
a first string selection transistor to an m-th string selection transistor respectively connected to a first string selection line to an m-th string selection line, wherein, based on the first cell string being a selected cell string:
the first to m-th string selection transistors of the first cell string are turned on, and
at least one of the first to m-th string selection transistors of each of the second to n-th cell strings is turned off, and
wherein m and n are natural numbers, and m is less than or equal to n.

2. The nonvolatile memory device of claim 1, wherein the n is calculated by n=C(m,[m/2]), and
wherein, for integers x and y greater than or equal to 0, C (x, y) is a first function indicating a number of cases of combining y out of x, and [x] is a second function indicating a largest integer not greater than x.

3. The nonvolatile memory device of claim 2, wherein, based on m being an even number, in each of the first to n-th cell strings, (m/2) string selection transistors among the first to m-th string selection transistors have a 0-th erase state, and remaining (m/2) string selection transistors among the first to m-th string selection transistors have a 0-th program state.

4. The nonvolatile memory device of claim 3, wherein, based on m being an even number:
in each of the first to n-th cell strings, the (m/2) string selection transistors having the 0-th erase state have a first threshold voltage, and
in each of the first to n-th cell strings, the (m/2) string selection transistors having the 0-th program state have a second threshold voltage, and
wherein the first threshold voltage is lower than the second threshold voltage.

5. The nonvolatile memory device of claim 4, wherein, based on m being an even number and the first cell string being the selected cell string:
in the first cell string, a first voltage is applied to (m/2) string selection lines respectively connected to the (m/2) string selection transistors having the 0-th erase state, and in the first cell string, a second voltage is applied to (m/2) string selection lines respectively connected to the (m/2) string selection transistors having the 0-th program state,
wherein the first voltage is higher than the first threshold voltage and is lower than the second threshold voltage, and
wherein the second voltage is higher than the second threshold voltage.

6. The nonvolatile memory device of claim 5, wherein, based on m being an even number and the first cell string being the selected cell string, in each of the second to n-th cell strings, the first voltage is applied to at least one of (m/2) string selection lines respectively connected to the (m/2) string selection transistors having the 0-th program state.

7. The nonvolatile memory device of claim 2, wherein, based on m being an odd number, in each of the first to n-th cell strings, ((m−1)/2) string selection transistors among the first to m-th string selection transistors have a 0-th erase state, and remaining ((m+1)/2) string selection transistors among the first to m-th string selection transistors have a 0-th program state.

8. The nonvolatile memory device of claim 7, wherein, based on m being an odd number:
in each of the first to n-th cell strings, the ((m−1)/2) string selection transistors having the 0-th erase state have a first threshold voltage, and
in each of the first to n-th cell strings, the ((m+1)/2) string selection transistors having the 0-th program state have a second threshold voltage, and
wherein the first threshold voltage is lower than the second threshold voltage.

9. The nonvolatile memory device of claim 8, wherein, based on m being an odd number and the first cell string being the selected cell string:
in the first cell string, a first voltage is applied to ((m−1)/2) string selection lines respectively connected to the ((m−1)/2) string selection transistors having the 0-th erase state, and
in the first cell string, a second voltage is applied to ((m+1)/2) string selection lines respectively connected to the ((m+1)/2) string selection transistors having the 0-th program state,
wherein the first voltage is higher than the first threshold voltage and is lower than the second threshold voltage, and
wherein the second voltage is higher than the second threshold voltage.

10. The nonvolatile memory device of claim 9, wherein, based on m being an odd number and the first cell string being the selected cell string,
in each of the second to n-th cell strings, the first voltage is applied to at least one of ((m+1)/2) string selection lines respectively connected to the ((m+1)/2) string selection transistors having the 0-th program state.

11. The nonvolatile memory device of claim 2, wherein, based on m being an odd number, in each of the first to n-th cell strings, ((m+1)/2) string selection transistors among the first to m-th string selection transistors have a 0-th erase state, and remaining ((m−1)/2) string selection transistors among the first to m-th string selection transistors have a 0-th program state.

12. The nonvolatile memory device of claim 1, wherein m is greater than or equal to 2,
wherein n is calculated by:
$$n = a + b$$
$$a = C ( m , [ ( m - 1 ) / 2 ] )$$
$$b = C ( m , [ ( m + 1 ) / 2 ] ) ,$$
and
wherein, for integers x and y greater than or equal to 0, C (x, y) is a first function indicating a number of cases of combining y out of x, and [x] is a second function indicating a largest integer not greater than x.

13. The nonvolatile memory device of claim 12, wherein, based on m being an odd number:
in each of the first to a-th cell strings, ((m−1)/2) string selection transistors among the first to m-th string selection transistors have a 0-th erase state, and remaining ((m+1)/2) string selection transistors among the first to m-th string selection transistors have a 0-th program state, and
in each of the (a+1)-th to n-th cell strings, ((m+1)/2) string selection transistors among the first to m-th string selection transistors have a 0-th erase state, and remaining ((m−1)/2) string selection transistors among the first to m-th string selection transistors have a first program state.

14. The nonvolatile memory device of claim 13, wherein, based on m being an odd number:
in each of the first to a-th cell strings, the ((m−1)/2) string selection transistors having the 0-th erase state have a first threshold voltage,
in each of the first to a-th cell strings, the ((m+1)/2) string selection transistors having the 0-th program state have a second threshold voltage,
in each of the (a+1)-th to n-th cell strings, the ((m+1)/2) string selection transistors having the 0-th erase state have the first threshold voltage, and
in each of the (a+1)-th to n-th cell strings, the ((m−1)/2) string selection transistors having the first program state have a third threshold voltage, and
wherein the second threshold voltage is higher than the first threshold voltage and is lower than the third threshold voltage.

15. The nonvolatile memory device of claim 14, wherein, based on m being an odd number and the first cell string being the selected cell string:
in the first cell string, a first voltage is applied to ((m−1)/2) string selection lines respectively connected to the ((m−1)/2) string selection transistors having the 0-th erase state, and
in the first cell string, a second voltage is applied to ((m+1)/2) string selection lines respectively connected to the ((m+1)/2) string selection transistors having the 0-th program state,
wherein the first voltage is higher than the first threshold voltage and is lower than the second threshold voltage, and
wherein the second voltage is higher than the second threshold voltage.

16. The nonvolatile memory device of claim 12, wherein, based on m being an even number:
in each of the first to a-th cell strings, ((m/2)−1) string selection transistors among the first to m-th string selection transistors have a 0-th erase state, and remaining ((m/2)+1) string selection transistors among the first to m-th string selection transistors have a 0-th program state, and
in each of the (a+1)-th to n-th cell strings, (m/2) string selection transistors among the first to m-th string selection transistors have a 0-th erase state, and remaining (m/2) string selection transistors among the first to m-th string selection transistors have a first program state.

17. A nonvolatile memory device comprising:
a first cell string to an n-th cell string connected between a bit line and each of a first common source line to an n-th common source line,
wherein each of the first to n-th cell strings comprises:
a corresponding one a first ground selection transistor to an n-th ground selection transistor connected to a ground selection line; and
a first string selection transistor to an m-th string selection transistor respectively connected to a first string selection line to an m-th string selection line, wherein, based on the first cell string being a selected cell string:
the first to m-th string selection transistors of the first cell string are turned on, and
at least one of the first to m-th string selection transistors of each of the second to n-th cell strings is turned off, and
wherein the m and are natural numbers, and m is less than or equal to n.

18. The nonvolatile memory device of claim 17, wherein the n is calculated by n=C(m,[m/2]), and
wherein, for integers x and y greater than or equal to 0, C(x, y) is a first function indicating a number of cases of combining y out of x, and [x] is a second function indicating a largest integer not greater than x.

19. The nonvolatile memory device of claim 17, wherein m is greater than or equal to 2, and
wherein n is calculated by:
$$n = a + b$$
$$a = C ( m , [ ( m - 1 ) / 2 ] )$$
$$b = C ( m , [ ( m + 1 ) / 2 ] ) ,$$
and
wherein, for integers x and y greater than or equal to 0, C(x, y) is a first function indicating a number of cases of combining y out of x, and [x] is a second function indicating a largest integer not greater than x.

20. A nonvolatile memory device comprising:
a plurality of cell strings provided between a bit line and a common source line, each of the plurality of cell strings comprising a plurality of string selection transistors connected to a plurality of string selection lines,
wherein, based on a first cell string among the plurality of cell strings being a selected cell string, in each of remaining unselected cell strings among the plurality of cell strings, at least one string selection transistor among the plurality of string selection transistors is turned off, and
wherein a number of the plurality of cell strings is more than a number of the plurality of string selection lines.
